(19) United States
(12) Patent Application Publication
(10) Pub. No.: US 2025/0098491 A1
(43) Pub. Date: Mar. 20, 2025

(54) DISPLAY PANEL, DISPLAY APPARATUS, AND METHOD FOR MANUFACTURING DISPLAY PANEL

(71) Applicant: Hefei Visionox Technology Co., Ltd., Hefei (CN)

(72) Inventors: Liusong NI, Hefei (CN); Yiming XIAO, Hefei (CN); Yuan YAO, Hefei (CN); Yi-Yu LAI, Hefei (CN); Xuejing ZHU, Hefei (CN)

(73) Assignee: Hefei Visionox Technology Co., Ltd., Hefei (CN)

(21) Appl. No.: 18/938,693

(22) Filed: Nov. 6, 2024

Related U.S. Application Data
(63) Continuation of application No. PCT/CN2024/098217, filed on Jun. 7, 2024.

(30) Foreign Application Priority Data
Jun. 9, 2023 (CN) 202310692518.5

(51) Int. Cl. H10K 59/80; H10K 59/12; H10K 59/122; H10K 71/20; H10K 102/00

(52) U.S. Cl. CPC H10K 59/873; H10K 59/1201; H10K 59/122; H10K 71/231; H10K 2102/351

(57) ABSTRACT

A display panel, a display apparatus, and a method for manufacturing a display panel. The display panel includes a substrate, an isolation structure, a light-emitting functional layer, and a first encapsulation layer, and the isolation structure is provided on a side of the substrate, and encloses and forms an opening structure. The light-emitting functional layer is provided on a side of the substrate and includes a plurality of light-emitting units provided within opening structures. The first encapsulation layer is provided on a side of the light-emitting functional layer away from the substrate and includes a plurality of encapsulation portions corresponding to the light-emitting units. Thicknesses of the encapsulation portions corresponding to at least a part of the light-emitting units having different light-emitting colors are different. In the embodiments of the present application, usage reliability of the display panel may be improved.

### CROSS-REFERENCE TO RELATED APPLICATION

The present application is a continuation application of International Application No. PCT/CN2024/098217, filed on Jun. 7, 2024, which claims priority to Chinese Patent Application No. 202310692518.5, filed on Jun. 9, 2023, and titled “DISPLAY PANEL, DISPLAY APPARATUS, AND METHOD FOR MANUFACTURING DISPLAY PANEL”, all of which are hereby incorporated by reference in their entireties.

### TECHNICAL FIELD

The present application relates to the field of display technology, and particularly to a display panel, a display apparatus, and a method for manufacturing a display panel.

### BACKGROUND

A flat display panel such as an organic light emitting diode (OLED) panel and a display panel using a light emitting diode (LED) device is widely used in various consumer electronic products such as mobile phones, TVs, personal digital assistants, digital cameras, notebook computers, desktop computers due to advantages of high image quality, power saving, thin body and wide application range, and becomes the mainstream in display devices.

### SUMMARY

Embodiments of the present application provide a display panel, a display apparatus, and a method for manufacturing a display panel, which can improve the display effect.

In a first aspect, the embodiments of the present application provide a display panel including:
a substrate;
an isolation structure provided on a side of the substrate, here, the isolation structure encloses and forms a plurality of opening structures;
a light-emitting functional layer provided on a side of the substrate, here, the light-emitting functional layer includes a plurality of light-emitting units provided within the plurality of opening structures; and
a first encapsulation layer provided on a side of the light-emitting functional layer away from the substrate, here, the first encapsulation layer includes a plurality of encapsulation portions corresponding to the light-emitting units;
here, thicknesses of the encapsulation portions corresponding to at least a part of the light-emitting units having different light-emitting colors are different.

The embodiments of the present application provide a display panel, a display apparatus, and a method for manufacturing a display panel. According to the manufacturing sequence of the light-emitting units within the display panel, the thicknesses of the encapsulation portions corresponding to at least a part of the light-emitting units having different light-emitting colors may be set to be different, and since the thicknesses of at least a part of the encapsulation portions are relatively great, the damage to the encapsulation portions by subsequent processes may be reduced more effectively, and the usage reliability of the display panel may be improved.

### BRIEF DESCRIPTION OF THE DRAWINGS

In order to more clearly illustrate the technical solutions of the embodiments of the present application, the drawings to be used in the embodiments of the present application will be briefly introduced below. For those of ordinary skill in the art, other drawings can be obtained based on these drawings without inventive effort.

FIG. 1 is a schematic sectional structural view of a display panel according to embodiments of the present application;

FIG. 2 is an enlarged schematic structural view of the region Q in FIG. 1;

FIG. 3A to FIG. 3B are top schematic structural views of an isolation structure and a light-emitting unit in another display panel according to embodiments of the present application;

FIG. 4 is a schematic sectional structural view of yet another display panel according to embodiments of the present application;

FIG. 5 is a schematic sectional structural view of yet another display panel according to embodiments of the present application;

FIG. 6 is a schematic sectional structural view of yet another display panel according to embodiments of the present application;

FIG. 7 is a schematic sectional structural view of yet another display panel according to embodiments of the present application;

FIG. 8 is a schematic structural view of a display apparatus according to embodiments of the present application;

FIG. 9 is a flowchart of a method for manufacturing a display panel according to embodiments of the present application;

FIG. 10A to FIG. 10E are schematic process structural view of a method for manufacturing a display panel according to embodiments of the present application;

FIG. 11 is a schematic sectional structural view of yet another display panel according to embodiments of the present application.

### DETAILED DESCRIPTION

Features and exemplary embodiments of various aspects of the present application will be described in detail below. In order to make the objectives, technical solutions, and advantages of the present application clearer, the present application will be further described in detail below with reference to the drawings and specific embodiments. It should be understood that the specific embodiments described herein are merely intended to explain the present application, rather than to limit the present application. For those skilled in the art, the present application can be implemented without some of these specific details. The following description of the embodiments is merely to provide a better understanding of the present application by illustrating the examples of the present application.

It should be noted that, in the present application, the relational terms, such as first and second, are used merely to distinguish one entity or operation from another entity or operation, without necessarily requiring or implying any actual such relationships or orders for these entities or operations. Moreover, the terms “comprise”, “include”, or any other variants thereof, are intended to represent a non-exclusive inclusion, such that a process, method, article or device including a series of elements includes not only those elements, but also other elements that are not explicitly listed or elements inherent to such a process, method, article or device. Without more constraints, the elements following an expression “comprise/include . . . ” do not exclude the existence of additional identical elements in the process, method, article or device that includes the elements.

In the related art, an isolation structure may be provided in a display panel, and a disconnection between different light-emitting units is achieved by the isolation structure, but in a process of using of the display panel, a problem of display failure occurs easily.

The inventors have found that this is because, in a process for manufacturing the display panel, a material for forming a light-emitting unit having a specific light-emitting color and an encapsulation material corresponding to the light-emitting unit both fall into opening structures formed by the isolation structure. The encapsulation material and the material for forming the light-emitting unit having the specific light-emitting color within a part of the opening structures need to be removed by an etching process to complete the manufacturing of the light-emitting unit and the corresponding encapsulation portion. Then, the above process is repeated to form a material of another light-emitting unit having a specific light-emitting color and an encapsulation material corresponding to the light-emitting unit in each opening structure, and then the encapsulation material and the corresponding light-emitting unit in a part of the opening structures are removed by a process such as etching. In this process, the etching process corresponding to the later-formed light-emitting unit easily damages the previously-formed light-emitting unit and the encapsulation material corresponding to the previously-formed light-emitting unit, resulting in the failure of a part of the light-emitting units and causing the risk of display abnormality.

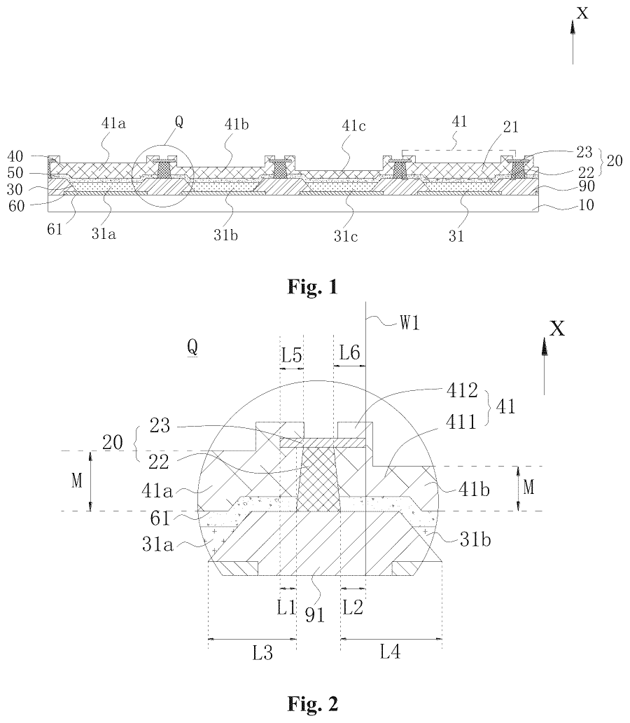

In view of this, in a first aspect, referring to FIG. 1 and FIG. 2, embodiments of the present application provide a display panel including a substrate 10, an isolation structure 20, a light-emitting functional layer 30, and a first encapsulation layer 40, the isolation structure 20 is provided on a side of the substrate 10, and the isolation structure 20 encloses and forms a plurality of opening structures 21. The light-emitting functional layer 30 is provided on a side of the substrate 10 and includes a plurality of light-emitting units 31 provided within a plurality of opening structures 31. The first encapsulation layer 40 is provided on a side of the light-emitting functional layer 30 away from the substrate 10 and includes a plurality of encapsulation portions 41 corresponding to the light-emitting units 31. Thicknesses M of the encapsulation portions 41 corresponding to at least a part of the light-emitting units 31 having different light-emitting colors are different.

The substrate 10 has a supporting and bearing function, other film layers are stacked in sequence on the substrate 10, and the “stacked” mentioned herein means that other film layers are provided in sequence along a thickness direction X of the substrate 10. Here, the substrate 10 may be provided with a plurality of film layer structures, and the composition of the film layer structures of the substrate 10 are not limited in the embodiments of the present application.

The isolation structure 20 may be located on a pixel definition layer, or the isolation structure 20 may be located on a planarization layer, and a location of the isolation structure 20 is not specifically limited herein.

The isolation structure 20 and the light-emitting functional layer 30 are located on the same side of the substrate 10, the isolation structure 20 encloses and forms a plurality of opening structures 21, and a size and a shape of the isolation structure 20 are not limited in the embodiments of the present application. In an example, referring to FIG. 1 to FIG. 3A, an orthographic projection of the isolation structure 20 on the substrate 10 is a mesh structure.

The light-emitting functional layer 30 includes a plurality of light-emitting units 31, the light-emitting unit 31 is a structure configured to achieve a light-emitting function and may emit light of a specific light-emitting color under the control of a circuit. The plurality of light-emitting units 31 are provided within the plurality of opening structures 21, respectively, and the plurality of light-emitting units 31 include, but are not limited to, a red light-emitting unit 31 configured to emit red light, a green light-emitting unit 31 configured to emit green light, and a blue light-emitting unit 31 configured to emit blue light. Each light-emitting unit 31 may include a hole inject layer (HIL), a hole transport layer (HTL), an electron blocking layer, a light-emitting material layer, an electron transport layer (ETL), a hole blocking layer, and an electron inject layer (EIL) provided in a stack.

The plurality of opening structures 21 enclosed and formed by the isolation structure 20 and the light-emitting units 31 may be in a one-to-one correspondence, and one light-emitting unit 31 is provided within one opening structure 21. Or, a plurality of light-emitting units 31 are provided within one opening structure 21, for example, a plurality of light-emitting units 31 having the same light-emitting color are provided within one opening structure 21.

The first encapsulation layer 40 is located on the side of the light-emitting functional layer 30 away from the substrate 10, and the first encapsulation layer 40 may be configured to protect the light-emitting unit 31, so that the probability of water, oxygen and the like intruding the light-emitting unit 31 is reduced, and the usage reliability of the light-emitting unit 31 is improved.

The first encapsulation layer 40 includes a plurality of encapsulation portions 41, the encapsulation portion 41 is a structure in the first encapsulation layer 40 covering at least one adjacent light-emitting unit 31, so that the encapsulation portion 41 may protect the at least one adjacent light-emitting unit 31. The encapsulation portion 41 is shown in a block in FIG. 1. Each of the encapsulation portions 41 corresponds to one light-emitting unit 31, so that the encapsulation of the light-emitting units 31 is achieved. In some embodiments, the plurality of light-emitting units 31 and the plurality of encapsulation portions 41 are in a one-to-one correspondence, so that independent encapsulation of the light-emitting units 31 is achieved. Or, one encapsulation portion 41 corresponds to the plurality of light-emitting units 31, and the plurality of light-emitting units 31 are encapsulated by the one encapsulation portion 41, for example, the plurality of light-emitting units 31 having the same light-emitting color are encapsulated by the one encapsulation portion 41.

On this basis, in the embodiment of the present application, thicknesses M of the encapsulation portions 41 corresponding to at least a part of the light-emitting units 31 having different light-emitting colors are different, so that the probability of failure of the light-emitting units 31 is reduced.

Specifically, an example is given in which the red light-emitting unit 31 is formed before the green light-emitting unit 31, and due to the presence of the isolation structure 20, the red light-emitting unit 31 and the corresponding encapsulation portion 41 are formed before the green light-emitting unit 31. Then, in the embodiments of the present application, a thickness M of an encapsulation portion 41 corresponding to the red light-emitting unit 31 may be adjusted according to the manufacturing sequence and increased properly, so that the thickness of the encapsulation portion 41 corresponding to the red light-emitting unit 31 is greater than a thickness M of an encapsulation portion 41 corresponding to the green light-emitting unit 31. In this way, under a condition that the green light-emitting unit 31 is etched and manufactured, the probability of damaging the encapsulation portion 41 corresponding to the red light-emitting unit 31 caused by etching is reduced, so that the effective encapsulation of the red light-emitting unit 31 is ensured, a risk of failure of the red light-emitting unit 31 is reduced, and the usage reliability of the display panel is improved.

Moreover, for various light-emitting units 31 having different light-emitting colors, thicknesses M of the encapsulation portions 41 corresponding to the various light-emitting units 31 may be set to be different or the same according to needs, which is not limited in the embodiments of the present application as long as thicknesses M of encapsulation portions 41 corresponding to a part of the light-emitting units 31 having different light-emitting colors in the display panel are different.

In summary, in the embodiments of the present application, according to the manufacturing sequence of the light-emitting units 31 within the display panel, the thicknesses M of the encapsulation portions 41 corresponding to at least a part of the light-emitting units 31 having different light-emitting colors may be set to be different, and since the thicknesses of at least a part of the encapsulation portions are relatively great, the damage to the encapsulation portions by subsequent processes may be reduced more effectively. For example, a thickness M of an encapsulation portion 41 corresponding to a light-emitting unit 31 formed previously is greater, so that the risk of damaging the encapsulation portion 41 corresponding to the light-emitting unit 31 formed previously is reduced under a condition that a light-emitting unit 31 formed later and a corresponding encapsulation material are etched, the risk of the failure of a part of the light-emitting units 31 is reduced, and the usage reliability of the display panel is improved. In addition, under a condition that the light-emitting unit 31 and the corresponding encapsulation portion 41 are formed later, the light-emitting unit 31 and the encapsulation portion 41 formed later cover the encapsulation portion 41 of the light-emitting unit 31 formed previously, and under a condition that the light-emitting unit 31 and the encapsulation portion 41 covering the encapsulation portion 41 of the light-emitting unit 31 formed previously are etched, and since a thickness of the encapsulation portion 41 corresponding to the light-emitting unit 31 formed later is relatively small, an etching duration may be reduced. In some embodiments, the isolation structure 20 may be an integrated structure, for example, the isolation structure 20 may be an inverted trapezoidal structure that may be formed by a layer of material. Or, the isolation structure 20 may be a separated structure, for example, the isolation structure 20 is a T-shaped structure or an I-shaped structure that may be formed by multiple layers of material. A shape of the isolation structure 20 is not limited herein as long as the isolation structure 20 can achieve the disconnection of the light-emitting functional layer.

In some embodiments, the encapsulation portion 41 includes a first portion 411, an orthographic projection of the first portion 411 on the substrate 10 is located outside an orthographic projection of the isolation structure 20 on the substrate 10, and thicknesses of first portions 411 corresponding to at least a part of the light-emitting units 31 having different light-emitting colors are different.

Each of the encapsulation portions 41 includes the first portion 411 and a second portion 412, and the first portion 411 is a portion of the encapsulation portion 41 corresponding to the opening structure 21, that is, an orthographic projection of the first portion 411 on the substrate 10 is located outside the orthographic projection of the isolation structure 20 on the substrate 10. The second portion 412 is a portion of the encapsulation portion 41 located on the isolation structure 20, and an orthographic projection of the second portion 412 on the substrate 10 is located within the orthographic projection of the isolation structure 20 on the substrate 10. In FIG. 2, a boundary line between the first portion 411 and the second portion 412 is shown as a straight line W.

In general, the first portion 411 encapsulates the light-emitting unit 31, and under a condition that the first portion 411 is damaged due to the etching process, abnormal failure of the corresponding light-emitting unit 31 occurs easily. In view of this, in the embodiments of the present application, the thicknesses of the first portions 411 corresponding to at least a part of the light-emitting units 31 having different light-emitting colors are set to be different, and thicknesses of first portions 411 of the encapsulation portions 41 corresponding to at least a part of the light-emitting units 31 formed previously are great to the greatest extent, so that the probability of completely damaging the first portions 411 formed previously by a subsequent etching process is reduced, so as to ensure that each light-emitting unit 31 may emit light reliably, and improve light-emitting reliability of the display panel.

In some embodiments, as shown in FIG. 1 and FIG. 2, the isolation structure 20 includes a first isolation portion 22 and a second isolation portion 23 provided in sequence along a thickness direction X away from the substrate 10, and an orthographic projection of the first isolation portion 22 on the substrate 10 is located within an orthographic projection of the second isolation portion 23 on the substrate 10. The orthographic projection of the first portion 411 on the substrate 10 is outside the orthographic projection of the second isolation portion 23 on the substrate 10.

The isolation structure 20 includes at least the first isolation portion 22 and the second isolation portion 23, and specific sizes of the first isolation portion 22 and the second isolation portion 23 are not limited in the embodiments of the present application. In an example, the orthographic projections of the first isolation portion 22 and the second isolation portion 23 on the substrate 10 are both mesh structures.

Since the orthographic projection of the first isolation portion 22 on the substrate 10 is located within the orthographic projection of the second isolation portion 23 on the substrate 10, the second isolation portion 23 extends at least partially beyond the first isolation portion 22 along a direction parallel to a plane where the substrate 10 is located. In the manufacturing process of the light-emitting unit 31, such design enables a light-emitting material falling within the opening structure 21 to be spaced apart from a light-emitting material located on a side of the second isolation portion 23 away from the substrate 10, thereby satisfying a manufacturing requirement for the light-emitting unit 31. It should be noted that, in an actual production process, a part of the light-emitting material may be in contact with a sidewall of the first isolation portion 22, which is not specifically limited herein.

In some embodiments, each of the encapsulation portions 41 includes the second portion 412 located on a side of the isolation structure 20 away from the substrate 10, and for the plurality of encapsulation portions 41 corresponding to the plurality of light-emitting units 31 having different light-emitting colors, thicknesses of second portions 412 of the plurality of encapsulation portions 41 are different.

In the embodiments of the present application, the thicknesses of the encapsulation portions 41 corresponding to at least a part of the light-emitting units 31 having different light-emitting colors may be set to be different according to the manufacturing sequence of the light-emitting units 31 within the display panel, so that thicknesses of second portions 412 corresponding to different encapsulation portions 41 are different. Here, a thickness of the second portion 412 of the encapsulation portion 41 corresponding to the light-emitting unit 31 formed previously is greater, so that the damage to the encapsulation portion 41 corresponding to the light-emitting unit 31 formed previously due to an etching treatment on the subsequent light-emitting unit 31 and the corresponding encapsulation material is reduced, the risk of the failure of a part of the light-emitting units 31 is reduced, and the usage reliability of the display panel is improved.

In some embodiments, the plurality of light-emitting units 31 include a first light-emitting unit 31a, a second light-emitting unit 31b, and a third light-emitting unit 31c having light-emitting colors different from each other, the plurality of encapsulation portions 41 include a first encapsulation portion 41a located on a side of the first light-emitting unit 31a away from the substrate 10, a second encapsulation portion 41b located on a side of the second light-emitting unit 31b away from the substrate 10, and a third encapsulation portion 41b located on a side of the third light-emitting unit 31c away from the substrate 10, and a thickness of the first encapsulation portion 41a is greater than a thickness of at least one of the second encapsulation portion 41b and the third encapsulation portion 41c.

Or, in some other embodiments, as shown in FIG. 1 and FIG. 2, the plurality of light-emitting units 31 include a first light-emitting unit 31a and a second light-emitting unit 31b having light-emitting colors different from each other.

The plurality of encapsulation portions 41 includes a first encapsulation portion 41a located on a side of the first light-emitting unit 31a away from the substrate 10 and a second encapsulation portion 41b located on a side of the second light-emitting unit 31b away from the substrate 10, and a thickness of the first encapsulation portion 41a is greater than a thickness of the second encapsulation portion 41b.

The plurality of encapsulation portions 41 include a third encapsulation portion 41c located on a side of the third light-emitting unit 31c away from the substrate 10, the thickness of the second encapsulation portion 41b is greater than a thickness of the third encapsulation portion 41c, or the thickness of the second encapsulation portion 41b is equal to the thickness of the third encapsulation portion 41c; or, the thickness of the first encapsulation portion 41a is equal to the thickness of the second encapsulation portion 41b, and the thickness of the second encapsulation portion 41b is greater than the thickness of the third encapsulation portion 41c.

Further, in some optional embodiments, the first light-emitting unit 31a is configured to emit red light, the second light-emitting unit 31b is configured to emit green light, and the third light-emitting unit 31c is configured to emit blue light. That is, the manufacturing sequence of the light-emitting units 31 may be red, green, and blue, and thicknesses of the corresponding encapsulation portions 41 tend to decrease gradually.

It should be noted that the first encapsulation portion 41a is an encapsulation portion protecting the first light-emitting unit 31a, the second encapsulation portion 41b is an encapsulation portion protecting the second light-emitting unit 31b, and the third encapsulation portion 41c is an encapsulation portion protecting the third light-emitting unit 31c. The first encapsulation portion 41a, the second encapsulation portion 41b, and the third encapsulation portion 41c each include the first portion 411 and the second portion 412.

Optionally, the first light-emitting unit 31a is configured to emit blue light, the second light-emitting unit 31b is configured to emit green light, and the third light-emitting unit 31c is configured to emit red light.

In the above optional embodiments, thicknesses of the encapsulation portions 41 corresponding to the first light-emitting unit 31a, the second light-emitting unit 31b, and the third light-emitting unit 31c are different.

In some other optional embodiments, thicknesses of the encapsulation portions 41 corresponding to two light-emitting units having two light-emitting colors among the first light-emitting unit 31a, the second light-emitting unit 31b, and the third light-emitting unit 31c are different.

For example, the first light-emitting unit 31a is configured to emit red light or green light, and the second light-emitting unit 31b is configured to emit blue light. Specifically, a thickness of the encapsulation portion 41 corresponding to the light-emitting unit configured to emit blue light is less than a thickness of the encapsulation portion 41 corresponding to the light-emitting unit configured to emit red light, and the thickness of the encapsulation portion 41 corresponding to the light-emitting unit configured to emit blue light is less than a thickness of the encapsulation portion 41 corresponding to the light-emitting unit configured to emit green light.

In some optional embodiments, a thickness of at least one encapsulation portion 41 is greater than or equal to 1 m, and less than or equal to 2.5 m.

In some embodiments, an etching selectivity ratio of the second encapsulation portion 41b to the first encapsulation portion 41a is SR1, and SR1≥1.

The “etching selectivity ratio” mentioned in the embodiments of the present application means how fast an etching rate of one material is relative to the other material under the same etching conditions, and the etching selectivity ratio is often related to a property of a material.

SR1≥1 means that an etching rate of the second encapsulation portion 41b is not less than an etching rate of the first encapsulation portion 41a. Further, since the thickness of the first encapsulation portion 41a is greater than the thickness of the second encapsulation portion 41b, an etching duration corresponding to the second encapsulation portion 41b is less than an etching duration corresponding to the first encapsulation portion 41a.

It may be seen from the foregoing that the second light-emitting unit 31b is formed after the first light-emitting unit 31a, therefore the second encapsulation portion 41b corresponding to the second light-emitting unit 31b is also formed after the first light-emitting unit 31a.

On this basis, in the embodiments of the present application, by controlling that the thickness of the second encapsulation portion 41b is less than the thickness of the first encapsulation portion 41a, and the etching selectivity ratio of the second encapsulation portion 41b to the first encapsulation portion 41a is not less than 1, the etching duration corresponding to the second encapsulation portion 41b is reduced, so that the etching duration corresponding to the second encapsulation portion 41b is less than the etching duration corresponding to the first encapsulation portion 41a, thereby reducing the probability of damaging the first encapsulation portion 41a due to over-etching of the second encapsulation portion 41b, and improving the encapsulation reliability of the first light-emitting unit 31a.

Similarly, in some embodiments, an etching selectivity ratio of the third encapsulation portion 41c to the second encapsulation portion is SR2, and SR2≥1. That is, it means that the etching rate of the third encapsulation portion 41c is not less than the etching rate of the second encapsulation portion 41b.

In such design, the etching duration corresponding to the third encapsulation portion 41c can be reduced, so that the etching duration corresponding to the third encapsulation portion 41c is less than the etching duration corresponding to the second encapsulation portion 41b, and the probability of damaging the second encapsulation portion 41b due to over-etching of the third encapsulation portion 41c may be reduced, thereby improving the encapsulation reliability of the second light-emitting unit 31b.

In some embodiments, a material of the first encapsulation portion 41a is the same as a material of the second encapsulation portion 41b.

In such design, it is not necessary to use different materials to manufacture the first encapsulation portion 41a and the second encapsulation portion 41b, respectively, so that material cost corresponding to the first encapsulation portion 41a and the second encapsulation portion 41b is reduced, and manufacturing cost of the display panel is reduced.

In some embodiments, SR1>1, the first encapsulation portion 41a includes silicon oxide, and the second encapsulation portion 41b includes silicon oxynitride. Under the same condition, an etching rate of silicon oxynitride is often greater than an etching rate of silicon oxide, and the thickness of the second encapsulation portion 41b is less than the thickness of the first encapsulation portion 41a, so that the etching duration corresponding to the second encapsulation portion 41b may be ensured to be less than the etching duration corresponding to the first encapsulation portion 41a, thereby improving manufacturing reliability of the display panel.

In some embodiments, SR2>1, the second encapsulation portion 41b includes silicon oxynitride, and the third encapsulation portion 41c includes silicon nitride. Under the same condition, an etching rate of silicon nitride is often greater than an etching rate of silicon oxynitride, and the thickness of the third encapsulation portion 41c is less than the thickness of the second encapsulation portion 41b, so that the etching duration corresponding to the third encapsulation portion 41c may be ensured to be less than the etching duration corresponding to the second encapsulation portion 41b, thereby improving manufacturing reliability of the display panel.

In some embodiments, referring to FIG. 1 to FIG. 3A, the isolation structure 20 includes a first isolation portion 22 and a second isolation portion 23 provided in sequence along a direction away from the substrate 10, and an orthographic projection of the first isolation portion 22 on the substrate 10 is located within an orthographic projection of the second isolation portion 23 on the substrate 10. The plurality of light-emitting units 31 include a first light-emitting unit 31a and a second light-emitting unit 31b having light-emitting colors different from each other, the plurality of opening structures 21 include at least one first opening structure 211 and at least one second opening structure 212, the first light-emitting unit 31a is located within the first opening structure 211, and the second light-emitting unit 31b is located within the second opening structure 212.

The plurality of encapsulation portions 41 includes a first encapsulation portion 41a located on a side of the first light-emitting unit 31a away from the substrate 10 and a second encapsulation portion 41b located on a side of the second light-emitting unit 31b away from the substrate 10, and a thickness of the first encapsulation portion 41a is greater than a thickness of the second encapsulation portion 41b. That is, manufacturing sequence of the first light-emitting units 31a is often before manufacturing sequence of the second light-emitting units 31b.

Optionally, a thickness of the encapsulation portion 41 corresponding to a light-emitting unit 31 having at least one light-emitting color is greater than 2 times a thickness of the first isolation portion. For example, thicknesses of encapsulation portions 41 corresponding to a light-emitting unit 31 emitting blue light and a light-emitting unit 31 emitting green light are greater than 2 times the thickness of the first isolation portion.

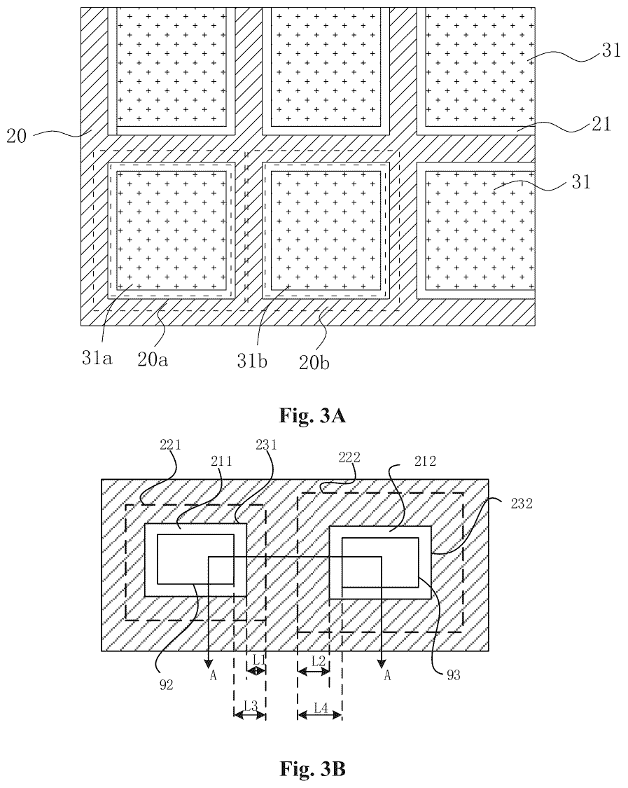

In some embodiments, FIG. 2 is a cross-sectional view of FIG. 3B along a direction AA. As shown in FIG. 2 and FIG. 3B, a contour line of the orthographic projection of the first isolation portion 22 on the substrate 10 includes a first contour line 221 corresponding to the first opening structure 211 and a second contour line 222 corresponding to the second opening structure 212; a contour line of the orthographic projection of the second isolation portion 23 on the substrate 10 includes a third contour line 231 corresponding to the first opening structure 211 and a fourth contour line 232 corresponding to the second opening structure 212; a distance between the first contour line 221 and the third contour line 231 is L1, a distance between the second contour line 222 and the fourth contour line 232 is L2, and L1<L2.

A length of the second isolation portion 23 extending toward the first opening structure 211 relative to the first isolation portion 22 is L5, a length of the second isolation portion 23 extending toward the second opening structure 212 relative to the first isolation portion 22 is L6, and L5<L6.

It should be noted that the first isolation structure 20a and the second isolation structure 20b each include the first isolation portion 22 and the second isolation portion 23, and the first isolation structure 20a may be connected to the second isolation structure 20b. Specifically, as shown in FIG. 2 and FIG. 3B, a part of the structure of the first isolation structure 20a and a part of the structure of the second isolation structure 20b may exist between the first light-emitting unit 31a and the second light-emitting unit 31b, and are connected to each other.

Since the manufacturing sequence of the first light-emitting units 31a is often before the manufacturing sequence of the second light-emitting units 31b, in an etching treatment corresponding to the first light-emitting units 31a, the first light-emitting unit 31a may exist within the opening structure 21 enclosed and formed by the first isolation structure 20a, and the light-emitting unit 31 does not exist within the opening structure 21 enclosed and formed by other parts of structures of the second isolation structure 20b and the isolation structure 20a. In the etching process, the first isolation portion 22 within the second isolation structure 20b is affected by the etching process and side-etched, and the first isolation portion 22 within the first isolation structure 20a is not side-etched or only side-etched to a relatively small extent, so that L1 corresponding to the first isolation structure 20a is less than L2 corresponding to the second isolation structure 20b.

In some embodiments, the isolation structure 20 includes a first isolation portion 22 and a second isolation portion 23 provided in sequence along a direction away from the substrate 10, and an orthographic projection of the first isolation portion 22 on the substrate 10 is located within an orthographic projection of the second isolation portion 23 on the substrate 10. The plurality of light-emitting units 31 include a first light-emitting unit 31a and a second light-emitting unit 31b having light-emitting colors different from each other, the isolation structure 20 includes a first isolation structure 20a and a second isolation structure 20b, the first light-emitting unit 31a is located within the opening structure 21 enclosed and formed by the first isolation structure 20a, and the second light-emitting unit 31b is located within the opening structure 21 enclosed and formed by the second isolation structure 20b. The first isolation structure 20a and the second isolation structure 20b are different structures of the isolation structure 20 at different positions, here, the first isolation structure 20a may be connected to the second isolation structure 20b, or the first isolation structure 20a may be spaced apart from the second isolation structure 20b.

The plurality of encapsulation portions 41 includes a first encapsulation portion 41a located on a side of the first light-emitting unit 31a away from the substrate 10 and a second encapsulation portion 41b located on a side of the second light-emitting unit 31b away from the substrate 10, and a thickness of the first encapsulation portion 41a is greater than a thickness of the second encapsulation portion 41b. That is, manufacturing sequence of the first light-emitting units 31a is often before manufacturing sequence of the second light-emitting units 31b.

As shown in FIG. 2 and FIG. 3B, the display panel further includes a pixel definition layer 90 including a plurality of pixel openings and a pixel definition portion 91 between adjacent pixel openings, the plurality of pixel openings includes a first pixel opening and a second pixel opening, the first light-emitting unit 31a is located within the first pixel opening, the second light-emitting unit 31b is located within the second pixel opening, the first pixel opening is in communication with the first opening structure 211, and the second pixel opening is in communication with the second opening structure 212. A contour line of the orthographic projection of the first isolation portion 22 on the substrate 10 includes a first contour line 221 corresponding to the first opening structure 211 and a second contour line 222 corresponding to the second opening structure 212; a contour line of an orthographic projection of the pixel defining portion 91 on the substrate 10 includes a fifth contour line 92 corresponding to the first pixel opening and a sixth contour line 93 corresponding to the second pixel opening; and a distance between the first contour line 221 and the fifth contour line 92 is L3, a distance between the second contour line 222 and the fourth contour line 93 is L4, and L3<L4.

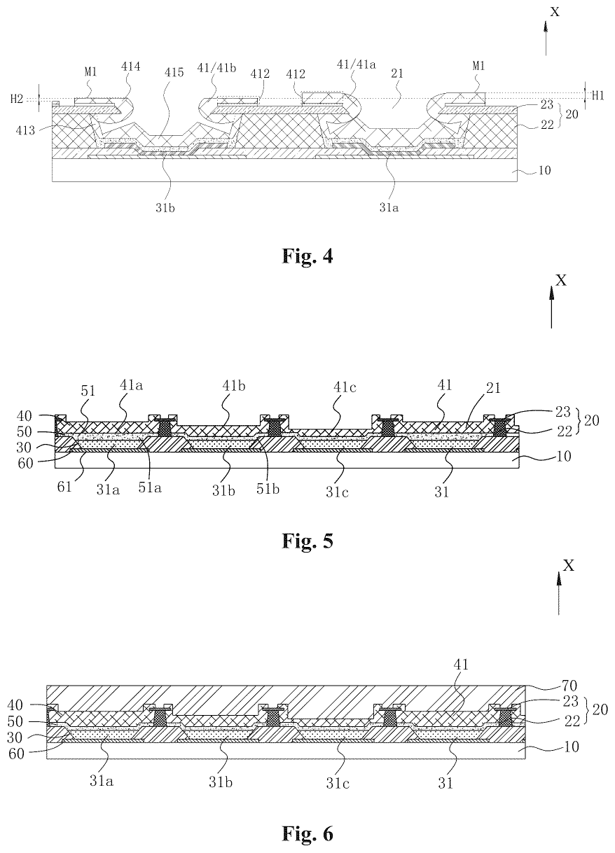

In some embodiments, referring to FIG. 4, the isolation structure 20 includes a first isolation portion 22 and a second isolation portion 23 provided in sequence along a direction away from the substrate 10, and an orthographic projection of the first isolation portion 22 on the substrate 10 is located within an orthographic projection of the second isolation portion 23 on the substrate 10.

The encapsulation portion 41 includes a first sub-portion 413 in contact with the first isolation portion 22, a second sub-portion 414 connected to a side of the first sub-portion 413 away from the substrate 10, and a third sub-portion 415 connected to a side of the first sub-portion 413 facing the substrate 10.

In the manufacturing process of the encapsulation portion 41, a corresponding encapsulation material may extend along a sidewall of the isolation structure 20, so that the formed encapsulation portion 41 includes the first sub-portion 413, the second sub-portion 414, and the third sub-portion 415, here, the first sub-portion 413 is in contact with a sidewall of the first isolation portion 22, and the second sub-portion 414 may partially be in contact with a sidewall of the second isolation portion 23 and partially extend to a side of the second isolation portion 23 away from the substrate 10, that is, the second sub-portion 414 may include a second portion 412. The third sub-portion 415 correspondingly covers the light-emitting unit 31.

It may be seen from the foregoing that, in the embodiments of the present application, thicknesses of different encapsulation portions 41 may be different, so that different encapsulation portions 41 may correspond to different microscopic appearances. Optionally, in at least a part of the encapsulation portions 41, the second sub-portion 414 is connected to the third sub-portion 415, that is, the first sub-portion 413, the second sub-portion 414, and the third sub-portion 415 can together form an enclosed space, and reference may be made to a microscopic appearance of the encapsulation portion 41 provided on the first light-emitting unit 31a in FIG. 4 for the specific detail. In at least a part of the encapsulation portion 41, the second sub-portion 414 is spaced apart from the third sub-portion 415, that is, the first sub-portion 413, the second sub-portion 414, and the third sub-portion 415 can together form a space having an opening, and reference may be made to a microscopic appearance of the encapsulation portion 41 provided on the second light-emitting unit 31b in FIG. 4 for the specific detail.

In some optional embodiments, the plurality of encapsulation portions 41 includes a first encapsulation portion 41a and a second encapsulation portion 41b. Here, a thickness of the first encapsulation portion 41a is greater than a thickness of the second encapsulation portion 41b. Further, the greater the thickness of the first encapsulation portion 41a is, the easier it is for the second sub-portion 414 within the first encapsulation portion 41a to be connected to the third sub-portion 415. Therefore, in the first encapsulation portion 41a, the second sub-portion 414 is connected to the third sub-portion 415, and in the second encapsulation portion 41b, the second sub-portion 414 is spaced apart from the third sub-portion 415.

In some embodiments, referring to FIG. 5, the display panel further includes a first electrode layer 50 provided between the light-emitting functional layer 30 and the first encapsulation layer 40, and the first electrode layer 50 includes a plurality of first electrodes 51 corresponding to the plurality of light-emitting units 31.

The first electrode layer 50 is located on a side of the light-emitting functional layer 30 away from the substrate 10 and includes the plurality of first electrodes 51 corresponding to the plurality of light-emitting units 31, and the first electrodes 51 are configured to drive the light-emitting units 31 to emit light and display. In an example, the first electrode 51 is a cathode.

Optionally, the display panel further includes a second electrode layer 60 located on a side of the light-emitting functional layer 30 facing the substrate 10, and the second electrode layer 60 includes a plurality of second electrodes 61 corresponding to the light-emitting units 31. In an example, the second electrode 61 is an anode, and the first electrode 51 and the second electrode 61 together drive the light-emitting unit 31 to emit light and display.

Due to the presence of the isolation structure 20, the first electrode layer 50 includes the plurality of first electrodes 51 located within different opening structures 21.

In some embodiments, thicknesses of first electrodes 51 corresponding to at least a part of the light-emitting units 31 having different light-emitting colors are different. In FIG. 5, a thickness of the first electrode 51 corresponding to the first light-emitting unit 31a is greater than a thickness of the first electrode 51 corresponding to the second light-emitting unit 31b.

The first electrode 51 is located between the light-emitting unit 31 and the encapsulation portion 41, and under a condition that the encapsulation portion 41 is over-etched, the first electrode 51 is exposed easily, causing the risk of the first electrode 51 being damaged by etching. On this basis, in the embodiments of the present application and according to the manufacturing sequence of the light-emitting units 31 having different light-emitting colors, a thickness of the first electrode 51 corresponding to the light-emitting unit 31 formed previously is relatively great, so that the first electrode 51 can have a certain risk resistance capability, the probability that the first electrode 51 corresponding to the light-emitting unit 31 formed previously is excessively damaged and does not operate normally due to the etching process of the encapsulation portion 41 corresponding to the subsequent light-emitting unit 31 is reduced, thereby improving the reliability of the first electrodes 51 corresponding to different light-emitting units 31, and ensuring that the display panel can be used normally.

In some embodiments, the isolation structure 20 includes a first isolation portion 22 and a second isolation portion 23 provided in sequence along a direction away from the substrate 10, and an orthographic projection of the first isolation portion 22 on the substrate 10 is located within an orthographic projection of the second isolation portion 23 on the substrate 10. The first isolation portion 22 includes a conductive material, and the first electrode 51 contacts the first isolation portion 22.

Due to the presence of the isolation structure 20, the first electrodes 51 corresponding to different light-emitting units 31 are spaced apart from each other. On this basis, in order to enable at least a part of the first electrodes 51 to obtain corresponding potential signals, in the embodiments of the present application, the first isolation portion 22 includes a conductive structure, and the first electrode 51 contacts the first isolation portion 22. In such design, at least a part of the first electrodes 51 may be electrically connected to the first isolation portions 22, and particular potential signals are transmitted to the first electrodes 51 through the first isolation portions 22, so that driving and control of at least a part of the first electrodes 51 are achieved.

In some embodiments, as shown in FIG. 5, the plurality of encapsulation portions 41 include a first encapsulation portion 41a and a second encapsulation portion 41b, and a thickness of the first encapsulation portion 41a is greater than a thickness of the second encapsulation portion 41b. The plurality of first electrodes 51 include a first type electrode 51a and a second type electrode 51b, the first type electrode 51a is located on a side of the first encapsulation portion 41a facing the substrate 10, the second type electrode 51b is located on a side of the second encapsulation portion 41b facing the substrate 10, and a thickness of the first type electrode 51a is greater than a thickness of the second type electrode 51b.

In the embodiments of the present application, in addition to the different encapsulation portions 41, the different first electrodes 51 may have a difference in thickness. Specifically, a first type electrode 51a having a greater thickness can be covered by a first encapsulation portion 41a having a greater thickness, so that the risk of damaging the first type electrode 51a is reduced, and the overall reliability is improved.

In some embodiments, the plurality of light-emitting units 31 include a first light-emitting unit 31a and a second light-emitting unit 31b having light-emitting colors different from each other, and a thickness of the first light-emitting unit 31a is less than a thickness of the second light-emitting unit 31b. The plurality of encapsulation portions 41 includes a first encapsulation portion 41a located on a side of the first light-emitting unit 31a away from the substrate 10 and a second encapsulation portion 41b located on a side of the second light-emitting unit 31b away from the substrate 10, and a thickness of the first encapsulation portion 41a is greater than a thickness of the second encapsulation portion 41b.

In the embodiments of the present application, in addition to the different encapsulation portions 41, the different light-emitting units 31 may have a difference in thickness. Specifically, a first light-emitting unit 31a having a relatively small thickness can be covered by a first encapsulation portion 41a having a relatively great thickness, so that the risk of damaging the first light-emitting unit 31a is reduced, and the overall reliability is improved.

Optionally, the first light-emitting unit 31a and the second light-emitting unit 31b each include a hole transport layer, an electron transport layer, and a light-emitting material between the hole transport layer and the electron transport layer, and a thickness of a light-emitting material in the first light-emitting unit 31a is less than a thickness of a light-emitting material in the second light-emitting unit 31b.

In some embodiments, referring to FIG. 6, the display panel further includes a second encapsulation layer 70 provided on a side of the first encapsulation layer 40 away from the substrate 10, the second encapsulation layer 70 covers the plurality of encapsulation portions 41 and includes a first surface on a side away from the substrate 10, and the first surface is parallel to a plane where the substrate 10 is located.

The first encapsulation layer 40 and the second encapsulation layer 70 together are configured to achieve an encapsulation effect on the display panel, and the second encapsulation layer 70 is located on a side of the first encapsulation layer 40 away from the substrate 10. It may be seen from the foregoing that thicknesses of the encapsulation portions 41 corresponding to at least a part of the light-emitting units 31 having different light-emitting colors are different, so that the side of the first encapsulation layer 40 away from the substrate 10 is not a flat surface, which may adversely affect an above film layer.

In view of this, in the manufacturing process of the embodiments of the present application, a size and a shape of the second encapsulation layer 70 are controlled, so that the second encapsulation layer 70 is an integral structure, a surface of a side of the second encapsulation layer 70 away from the substrate 10 can be parallel to a plane where the substrate 10 is located, and an effect on manufacturing of subsequent film layers is reduced.

Optionally, the second encapsulation layer 70 may include an organic material, the organic material typically has a relatively high levelling property, which is helpful for achieving flatness of the surface of the side of the second encapsulation layer 70 away from the substrate 10 under a condition that the second encapsulation layer 70 is formed.

As shown in FIG. 6, since the second encapsulation layer 70 has a relatively high levelling property, the side of the second encapsulation layer 70 away from the substrate 10 is a plane. Therefore, under a condition that a thickness of the first encapsulation portion 41a is greater than a thickness of the second encapsulation portion 41b, a thickness of the second package layer 70 on the first encapsulation portion 41a is less than a thickness of the second package layer 70 on the second encapsulation portion 41b.

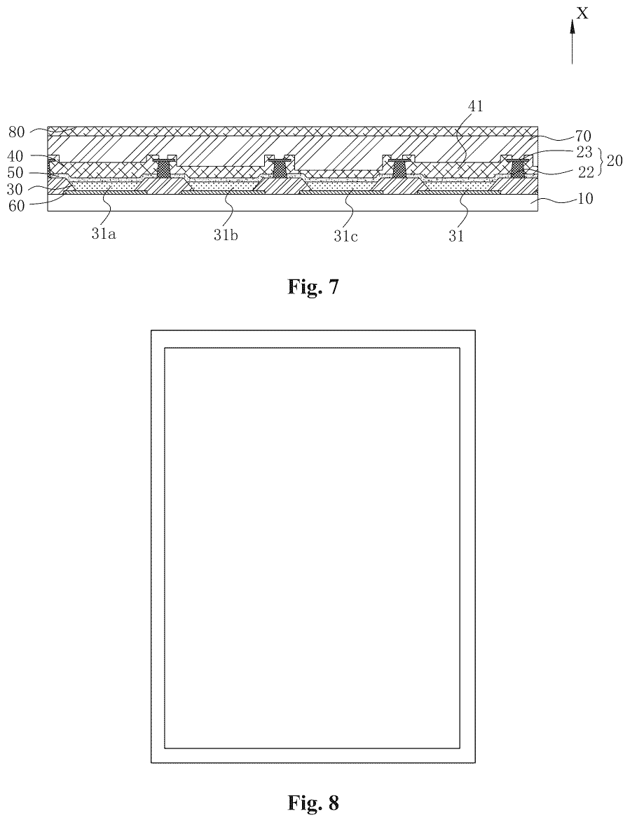

In some embodiments, referring to FIG. 7, the display panel further includes a third encapsulation layer 80 provided on a side of the second encapsulation layer 70 away from the substrate 10, and the third encapsulation layer 80 covers the plurality of encapsulation portions 41.

What is similar to the second encapsulation layer 70 is that the third encapsulation layer 80 is also an integral structure and can cover the plurality of encapsulation portions 41. Here, the first encapsulation layer 40, the second encapsulation layer 70, and the third encapsulation layer 80 may together form a thin film encapsulation structure, so that the encapsulation effect of the display panel is improved.

Optionally, the first encapsulation layer 40 and the third encapsulation layer 80 include an inorganic material.

In some embodiments, thicknesses of the encapsulation portions 41 corresponding to at least a part of the light-emitting units 31 having different light-emitting colors are different.

In the embodiments of the present application, according to the manufacturing sequence of the light-emitting units 31 having different light-emitting colors, thicknesses of corresponding encapsulation portions 41 are set to be decreased gradually, which is helpful for ensuring the reliability of the encapsulation portion 41 corresponding to the light-emitting unit 31 and ensuring the reliability of the light-emitting unit 31. Optionally, thicknesses of the encapsulation portions 41 corresponding to the light-emitting units 31 having the same light-emitting color are the same.

In some optional embodiments, thicknesses of the encapsulation portions 41 corresponding to at least two adjacent light-emitting units 31 are different.

In a second aspect, the embodiments of the present application provide a display panel including a substrate 10, an isolation structure 20, a light-emitting functional layer 30, and a first encapsulation layer 40, the isolation structure 20 is provided on a side of the substrate 10, and the isolation structure 20 encloses and forms a plurality of opening structures 21. The light-emitting functional layer 30 is provided on a side of the substrate 10 and includes a plurality of light-emitting units 31 provided within a plurality of opening structures 31. The first encapsulation layer 40 is provided on a side of the light-emitting functional layer 30 away from the substrate 10 and includes a plurality of encapsulation portions 41 corresponding to the light-emitting units 31.

The display panel further includes a second encapsulation layer 70 provided on a side of the first encapsulation layer 40 away from the substrate 10, the second encapsulation layer 70 covers the plurality of encapsulation portions 41, the second encapsulation layer 70 includes a first surface away from the substrate 10, and the first surface is parallel to a plane where the substrate 10 is located.

The substrate 10 has a supporting and bearing function, other film layers are stacked in sequence on the substrate 10, and the “stacked” mentioned herein means that other film layers are provided in sequence along a thickness direction X of the substrate 10. Here, the substrate 10 may be provided with a plurality of film layer structures, and the composition of the film layer structures of the substrate 10 are not limited in the embodiments of the present application.

The isolation structure 20 may be located on a pixel definition layer, or the isolation structure 20 may be located on a planarization layer, and a location of the isolation structure 20 is not specifically limited herein.

The isolation structure 20 and the light-emitting functional layer 30 are located on the same side of the substrate 10, the isolation structure 20 encloses and forms a plurality of opening structures 21, and a size and a shape of the isolation structure 20 are not limited in the embodiments of the present application. In an example, referring to FIG. 1 to FIG. 3B, an orthographic projection of the isolation structure 20 on the substrate 10 is a mesh structure.

The light-emitting functional layer 30 includes a plurality of light-emitting units 31, the light-emitting unit 31 is a structure configured to achieve a light-emitting function and may emit light of a specific light-emitting color under the control of a circuit. The plurality of light-emitting units 31 are provided within the plurality of opening structures 21, respectively, and the plurality of light-emitting units 31 include, but are not limited to, a red light-emitting unit 31 configured to emit red light, a green light-emitting unit 31 configured to emit green light, and a blue light-emitting unit 31 configured to emit blue light. Each light-emitting unit 31 may include a hole inject layer (HIL), a hole transport layer (HTL), an electron blocking layer, a light-emitting material layer, an electron transport layer (ETL), a hole blocking layer, and an electron inject layer (EIL) provided in a stack.

The plurality of opening structures 21 enclosed and formed by the isolation structure 20 and the light-emitting units 31 may be in a one-to-one correspondence, and one light-emitting unit 31 is provided within one opening structure 21. Or, a plurality of light-emitting units 31 are provided within one opening structure 21, for example, a plurality of light-emitting units 31 having the same light-emitting color are provided within one opening structure 21.

The first encapsulation layer 40 is located on the side of the light-emitting functional layer 30 away from the substrate 10, and the first encapsulation layer 40 may be configured to protect the light-emitting unit 31, so that the probability of water, oxygen and the like intruding the light-emitting unit 31 is reduced, and the usage reliability of the light-emitting unit 31 is improved.

The first encapsulation layer 40 includes a plurality of encapsulation portions 41, the encapsulation portion 41 is a structure of the first encapsulation layer 40 that protects a single light-emitting unit 31, and the encapsulation portion 41 is shown in a block in FIG. 1. Each of the encapsulation portions 41 corresponds to one light-emitting unit 31, so that the encapsulation of the light-emitting units 31 is achieved. In some embodiments, the plurality of light-emitting units 31 and the plurality of encapsulation portions 41 are in a one-to-one correspondence, so that independent encapsulation of the light-emitting units 31 is achieved. Or, one encapsulation portion 41 corresponds to the plurality of light-emitting units 31, and the plurality of light-emitting units 31 are encapsulated by the one encapsulation portion 41, for example, the plurality of light-emitting units 31 having the same light-emitting color are encapsulated by the one encapsulation portion 41.

The first encapsulation layer 40 and the second encapsulation layer 70 together are configured to achieve an encapsulation effect on the display panel, and the second encapsulation layer 70 is located on a side of the first encapsulation layer 40 away from the substrate 10. It may be seen from the foregoing that thicknesses of the encapsulation portions 41 corresponding to at least a part of the light-emitting units 31 having different light-emitting colors are different, so that the side of the first encapsulation layer 40 away from the substrate 10 is not a flat surface, which may adversely affect an above film layer.

In view of this, in the manufacturing process of the embodiments of the present application, a size and a shape of the second encapsulation layer 70 are controlled, so that the second encapsulation layer 70 is an integral structure, a surface of a side of the second encapsulation layer 70 away from the substrate 10 can be parallel to a plane where the substrate 10 is located, and an effect on manufacturing of subsequent film layers is reduced.

Optionally, the second encapsulation layer 70 may include an organic material, the organic material typically has a relatively high levelling property, which is helpful for achieving flatness of the surface of the side of the second encapsulation layer 70 away from the substrate 10 under a condition that the second encapsulation layer 70 is formed.

In a third aspect, the embodiments of the present application provide a display panel including a substrate, an isolation structure, a light-emitting functional layer, and a first encapsulation layer, the isolation structure is provided on a side of the substrate, and the isolation structure encloses and forms a plurality of opening structures. The light-emitting functional layer is provided on a side of the substrate and includes a plurality of light-emitting units provided within opening structures. The first encapsulation layer is provided on a side of the light-emitting functional layer away from the substrate and includes a plurality of encapsulation portions corresponding to the light-emitting units. Here, materials of the encapsulation portions corresponding to at least a part of the light-emitting units having different light-emitting colors are different.

In some embodiments, etching rates of the encapsulation portions corresponding to at least a part of the light-emitting units having different light-emitting colors are different. Specifically, the plurality of light-emitting units includes a first light-emitting unit, a second light-emitting unit, and a third light-emitting unit having light-emitting colors different from each other, the plurality of encapsulation portions include a first encapsulation portion located on a side of the first light-emitting unit away from the substrate, a second encapsulation portion located on a side of the second light-emitting unit away from the substrate, and a third encapsulation portion located on a side of the third light-emitting unit away from the substrate, and etching rates of at least two encapsulation portions of the first encapsulation portion, the second encapsulation portion, and the third encapsulation portion are different.

For example, the first light-emitting unit is configured to emit red light, the second light-emitting unit is configured to emit green light, the third light-emitting unit is configured to emit blue light, and etching rates of the first encapsulation portion, the second encapsulation portion, and the third encapsulation portion are increased in sequence. In the embodiments of the present application, according to the manufacturing sequence of the light-emitting units in the display panel, materials of the encapsulation portions corresponding to at least a part of the light-emitting units having different light-emitting colors are set to be different, so that an etching duration of an encapsulation portion corresponding to a light-emitting unit formed later is less than an etching duration of an encapsulation portion corresponding to a light-emitting unit formed previously, thereby reducing the risk of failure of a part of the light-emitting units caused by the damage to the encapsulation portions corresponding to the light-emitting units formed previously due to the etching treatment of the subsequent light-emitting unit and the corresponding encapsulation material, and improving the usage reliability of the display panel.

It should be noted that, in the embodiments of the present application, thicknesses of different encapsulation portions may be the same or different, which is not limited in the embodiments of the present application.

In some embodiments, the plurality of light-emitting units 31 include a first light-emitting unit 31a and a second light-emitting unit 31b having light-emitting colors different from each other, the plurality of encapsulation portions 41 include a first encapsulation portion 41a located on a side of the first light-emitting unit 31a away from the substrate 10 and a second encapsulation portion 41b located on a side of the second light-emitting unit 31b away from the substrate 10, an etching selectivity ratio of the second encapsulation portion 41b to the first encapsulation portion 41a is SR1, and SR1≥1.

The “etching selectivity ratio” mentioned in the embodiments of the present application means how fast an etching rate of one material is relative to the other material under the same etching conditions, and the etching selectivity ratio is often related to a property of a material.

SR1≥1 means that an etching rate of the second encapsulation portion 41b is not less than an etching rate of the first encapsulation portion 41a. Further, since the thickness of the first encapsulation portion 41a is greater than the thickness of the second encapsulation portion 41b, an etching duration corresponding to the second encapsulation portion 41b is less than an etching duration corresponding to the first encapsulation portion 41a.

It may be seen from the foregoing that the second light-emitting unit 31b is formed after the first light-emitting unit 31a, therefore the second encapsulation portion 41b corresponding to the second light-emitting unit 31b is also formed after the first light-emitting unit 31a.

On this basis, in the embodiments of the present application, by controlling that the thickness of the second encapsulation portion 41b is less than the thickness of the first encapsulation portion 41a, and the etching selectivity ratio of the second encapsulation portion 41b to the first encapsulation portion 41a is not less than 1, the etching duration corresponding to the second encapsulation portion 41b is reduced, so that the etching duration corresponding to the second encapsulation portion 41b is less than the etching duration corresponding to the first encapsulation portion 41a, thereby reducing the probability of damaging the first encapsulation portion 41a due to over-etching of the second encapsulation portion 41b, and improving the encapsulation reliability of the first light-emitting unit 31a.

Similarly, in some embodiments, an etching selectivity ratio of the third encapsulation portion 41c to the second encapsulation portion is SR2, and SR2≥1. That is, it means that the etching rate of the third encapsulation portion 41c is not less than the etching rate of the second encapsulation portion 41b.

In such design, the etching duration corresponding to the third encapsulation portion 41c can be reduced, so that the etching duration corresponding to the third encapsulation portion 41c is less than the etching duration corresponding to the second encapsulation portion 41b, and the probability of damaging the second encapsulation portion 41b due to over-etching of the third encapsulation portion 41c may be reduced, thereby improving the encapsulation reliability of the second light-emitting unit 31b.

In some embodiments, a material of the first encapsulation portion 41a is the same as a material of the second encapsulation portion 41b.

In such design, it is not necessary to use different materials to manufacture the first encapsulation portion 41a and the second encapsulation portion 41b, respectively, so that material cost corresponding to the first encapsulation portion 41a and the second encapsulation portion 41b is reduced, and manufacturing cost of the display panel is reduced.

In some embodiments, SR1>1, the first encapsulation portion 41a includes silicon oxide, and the second encapsulation portion 41b includes silicon oxynitride. Under the same condition, an etching rate of silicon oxynitride is often greater than an etching rate of silicon oxide, and the thickness of the second encapsulation portion 41b is less than the thickness of the first encapsulation portion 41a, so that the etching duration corresponding to the second encapsulation portion 41b may be ensured to be less than the etching duration corresponding to the first encapsulation portion 41a, thereby improving manufacturing reliability of the display panel.

In some embodiments, SR2>1, the second encapsulation portion 41b includes silicon oxynitride, and the third encapsulation portion 41c includes silicon nitride. Under the same condition, an etching rate of silicon nitride is often greater than an etching rate of silicon oxynitride, and the thickness of the third encapsulation portion 41c is less than the thickness of the second encapsulation portion 41b, so that the etching duration corresponding to the third encapsulation portion 41c may be ensured to be less than the etching duration corresponding to the second encapsulation portion 41b, thereby improving manufacturing reliability of the display panel.

In some optional embodiments, thicknesses of the encapsulation portions 41 corresponding to at least two adjacent light-emitting units 31 are different.

In a fourth aspect, as shown in FIG. 4, the embodiments of the present application provide a display panel including a substrate 10, an isolation structure 20, a light-emitting functional layer 30, and a first encapsulation layer 40, the isolation structure 20 is provided on a side of the substrate 10, and the isolation structure 20 encloses and forms a plurality of opening structures 21. The light-emitting functional layer 30 is provided on a side of the substrate 10 and includes a plurality of light-emitting units 31 provided within a plurality of opening structures 31. The first encapsulation layer 40 is provided on a side of the light-emitting functional layer 30 away from the substrate 10 and includes a plurality of encapsulation portions 41 corresponding to the plurality of light-emitting units 31. Here, the encapsulation portion 41 includes a second portion 412 located on a side of the isolation structure 20 away from the substrate 10, and thicknesses of second portions 412 corresponding to different encapsulation portions 41 are different.

In the embodiments of the present application, the thicknesses of the encapsulation portions 41 corresponding to at least a part of the light-emitting units 31 having different light-emitting colors may be set to be different according to the manufacturing sequence of the light-emitting units 31 within the display panel, so that thicknesses of second portions 412 corresponding to different encapsulation portions 41 are different. Here, a thickness of the second portion 412 of the encapsulation portion 41 corresponding to the light-emitting unit 31 formed previously is greater, so that the damage to the encapsulation portion 41 corresponding to the light-emitting unit 31 formed previously due to a subsequent etching treatment on the light-emitting unit 31 and the corresponding encapsulation material is reduced, the risk of the failure of a part of the light-emitting units 31 is reduced, and the usage reliability of the display panel is improved.

In some embodiments, the second portion 412 includes a first surface M1 away from the substrate 10, and first surfaces M1 corresponding to different encapsulation portions 41 are located on different planes.

The first surface M1 is a surface of a side of the second portion 412 away from the substrate 10, and in conjunction with the foregoing, it may be seen that the thicknesses of the second portions 412 corresponding to different encapsulation portions 41 are different, so that the usage reliability of the display panel is improved. Further, the first surfaces M1 corresponding to different encapsulation portions 41 are located on different planes, that is, different first surfaces M1 are spaced apart along the thickness direction X.

Optionally, as shown in FIG. 4, the plurality of encapsulation portions 41 includes a first encapsulation portion 41a and a second encapsulation portion 41b adjacent to each other, and a first surface M1 corresponding to the first encapsulation portion 41a and a first surface M1 corresponding to the second encapsulation portion 41b have a height difference H1 along the thickness direction X of the substrate 10.

In some optional embodiments, the plurality of encapsulation portions 41 includes a third encapsulation portion provided adjacent to the second encapsulation portion 41b and on a side of the second encapsulation portion 41b away from the first encapsulation portion 41a. A first surface M1 corresponding to the third encapsulation portion and the first surface M1 corresponding to the second encapsulation portion 41b have a height difference H2 along the thickness direction X of the substrate 10, and H1 H2.

In a sixth aspect, as shown in FIG. 1 and FIG. 2, the embodiments of the present application provide a display panel including a substrate 10, an isolation structure 20, a light-emitting functional layer 30, and a first encapsulation layer 40, the isolation structure 20 is provided on a side of the substrate 10, and the isolation structure 20 encloses and forms a plurality of opening structures 21. The light-emitting functional layer 30 is provided on a side of the substrate 10 and includes a plurality of light-emitting units 31 provided within a plurality of opening structures 31. The first encapsulation layer 40 is provided on a side of the light-emitting functional layer 30 away from the substrate 10 and includes a plurality of encapsulation portions 41 corresponding to the plurality of light-emitting units 31.

The isolation structure 20 includes a first isolation portion 22 and a second isolation portion 23 provided in sequence along a direction away from the substrate 10, and an orthographic projection of the first isolation portion 22 on the substrate 10 is located within an orthographic projection of the second isolation portion 23 on the substrate 10. The plurality of light-emitting units 31 include a first light-emitting unit 31a and a second light-emitting unit 31b having light-emitting colors different from each other, the isolation structure 20 includes a first isolation structure 20a and a second isolation structure 20b, the first light-emitting unit 31a is located within the opening structure 21 enclosed and formed by the first isolation structure 20a, and the second light-emitting unit 31b is located within the opening structure 21 enclosed and formed by the second isolation structure 20b. The first isolation structure 20a and the second isolation structure 20b are partial structures of the isolation structure 20 at different positions, here, the first isolation structure 20a may be connected to the second isolation structure 20b, or the first isolation structure 20a may be spaced apart from the second isolation structure 20b.

The plurality of encapsulation portions 41 includes a first encapsulation portion 41a located on a side of the first light-emitting unit 31a away from the substrate 10 and a second encapsulation portion 41b located on a side of the second light-emitting unit 31b away from the substrate 10, and a thickness of the first encapsulation portion 41a is greater than a thickness of the second encapsulation portion 41b. That is, manufacturing sequence of the first light-emitting units 31a is often before manufacturing sequence of the second light-emitting units 31b.

Further, in the first isolation portion structure 20a, a distance between an outer contour of an orthographic projection of the first isolation portion 22 on the substrate 10 and an outer contour of an orthographic projection of the second isolation portion 23 on the substrate 10 is L1, and in the second isolation portion structure 20b, a distance between an outer contour of an orthographic projection of the first isolation portion 22 on the substrate 10 and an outer contour of an orthographic projection of the second isolation portion 23 on the substrate 10 is L2, and L1<L2.

Since the manufacturing sequence of the first light-emitting units 31a is often before the manufacturing sequence of the second light-emitting units 31b, in an etching treatment corresponding to the first light-emitting units 31a, the first light-emitting unit 31a may exist within the opening structure 21 enclosed and formed by the first isolation structure 20a, and the light-emitting unit 31 does not exist within the opening structure 21 enclosed and formed by other parts of structures of the second isolation structure 20b and the isolation structure 20a. In the etching process, the first isolation portion 22 within the second isolation structure 20b is affected by the etching process and side-etched, and the first isolation portion 22 within the first isolation structure 20a is not side-etched or only side-etched to a relatively small extent, so that L1 corresponding to the first isolation structure 20a is less than L2 corresponding to the second isolation structure 20b.

In some embodiments, the display panel further includes a pixel definition layer 90 including a first pixel definition portion and a second pixel definition portion, a pixel opening enclosed and formed by the first pixel definition portion is in communication with the first isolation structure 20a, a pixel opening enclosed and formed by the second pixel definition portion is in communication with the second isolation structure 20b, the first light-emitting unit 31a is located within the pixel opening enclosed and formed by the first pixel definition portion, and the second light-emitting unit 31b is located in the pixel opening enclosed and formed by the second pixel definition portion. The first pixel definition portion and the second pixel definition portion are different structures of the pixel definition layer 90 at different locations, here, the first pixel definition portion may be connected to the second pixel definition portion, or the first pixel definition portion may be spaced apart from the second pixel definition portion.

Further, a distance between an outer contour of an orthographic projection of the first isolation portion 22 of the first isolation structure 20a on the substrate 10 and an outer contour of an orthographic projection of the first pixel definition portion 20a on the substrate is L3, a distance between an outer contour of an orthographic projection of the first isolation portion 22 of the second isolation structure 20b on the substrate 10 and an outer contour of an orthographic projection of the second pixel definition portion on the substrate 10 is L4, and L3<L4.

Since the manufacturing sequence of the first light-emitting units 31a is often before the manufacturing sequence of the second light-emitting units 31b, in an etching treatment corresponding to the first light-emitting units 31a, the first light-emitting unit 31a may exist within the opening structure 21 enclosed and formed by the first isolation structure 20a, and the light-emitting unit 31 does not exist within the opening structure 21 enclosed and formed by other parts of structures of the second isolation structure 20b and the isolation structure 20a. In the etching process, the first isolation portion 22 within the second isolation structure 20b is affected by the etching process and side-etched, and the first isolation portion 22 within the first isolation structure 20a is not side-etched or only side-etched to a relatively small extent, so that L3 corresponding to the first isolation structure 20a is less than L4 corresponding to the second isolation structure 20b.

In some embodiments, the encapsulation portion 41 includes a first portion 411, an orthographic projection of the first portion 411 on the substrate 10 is located outside an orthographic projection of the isolation structure 23 on the substrate 10, and thicknesses of first portions 411 corresponding to the first encapsulation portion 41a and the second encapsulation portion 41b are different.

The encapsulation portion 41 includes the first portion 411 and a second portion 412, the first portion 411 corresponds to the opening structure 21, that is, the orthographic projection of the first portion 411 on the substrate 10 is located outside the orthographic projection of the isolation structure 20 on the substrate 10, and an orthographic projection of the second portion 412 on the substrate 10 is located within the orthographic projection of the isolation structure 20 on the substrate 10. In FIG. 2, a boundary line between the first portion 411 and the second portion 412 is shown as a straight line.

In general, the first portion 411 encapsulates the light-emitting unit 31, and under a condition that the first portion 411 is damaged due to the etching process, abnormal failure of the corresponding light-emitting unit 31 occurs easily. In view of this, in the embodiments of the present application, the thicknesses of the first portions 411 corresponding to at least a part of the light-emitting units 31 having different light-emitting colors are set to be different, and thicknesses of first portions 411 of the encapsulation portions 41 corresponding to at least a part of the light-emitting units 31 formed previously are ensured to be great to the greatest extent, so that the probability of completely damaging the first portions 411 formed previously by a subsequent etching process is reduced, so as to ensure that each light-emitting unit 31 may emit light reliably, and improve light-emitting reliability of the display panel. Optionally, the orthographic projection of the first portion 411 on the substrate 10 is located outside the orthographic projection of the second isolation portion 23 on the substrate 10.

Since the orthographic projection of the first isolation portion 22 on the substrate 10 is located within the orthographic projection of the second isolation portion 23 on the substrate 10, the second isolation portion 23 extends at least partially beyond the first isolation portion 22 along a direction parallel to a plane where the substrate 10 is located. In the manufacturing process of the light-emitting unit 31, such design enables a light-emitting material falling within the opening structure 21 to be spaced apart from a light-emitting material located on a side of the second isolation portion 23 away from the substrate 10, thereby satisfying a manufacturing requirement for the light-emitting unit 31. It should be noted that, in an actual production process, a part of the light-emitting material may be in contact with a sidewall of the first isolation portion 22, which is not specifically limited herein.

In some embodiments, each of the encapsulation portions 41 includes a second portion 412 located on a side of the isolation structure 20 away from the substrate 10, and a thickness of a second portion 412 corresponding to the first encapsulation portion 41a is different from a thickness of a second portion 412 corresponding to the second encapsulation portion 41b.

In the embodiments of the present application, the thicknesses of the encapsulation portions 41 corresponding to at least a part of the light-emitting units 31 having different light-emitting colors may be set to be different according to the manufacturing sequence of the light-emitting units 31 within the display panel, so that thicknesses of second portions 412 corresponding to different encapsulation portions 41 are different. Here, a thickness of the second portion 412 of the encapsulation portion 41 corresponding to the light-emitting unit 31 formed previously is greater, so that the damage to the encapsulation portion 41 corresponding to the light-emitting unit 31 formed previously due to an etching treatment on the subsequent light-emitting unit 31 and the corresponding encapsulation material is reduced, the risk of the failure of a part of the light-emitting units 31 is reduced, and the usage reliability of the display panel is improved.

In some embodiments, an etching selectivity ratio of the second encapsulation portion 41b to the first encapsulation portion 41a is SR1, and SR1≥1.

The “etching selectivity ratio” mentioned in the embodiments of the present application means how fast an etching rate of one material is relative to the other material under the same etching conditions, and the etching selectivity ratio is often related to a property of a material.

SR1≥1 means that an etching rate of the second encapsulation portion 41b is not less than an etching rate of the first encapsulation portion 41a. Further, since the thickness of the first encapsulation portion 41a is greater than the thickness of the second encapsulation portion 41b, an etching duration corresponding to the second encapsulation portion 41b is less than an etching duration corresponding to the first encapsulation portion 41a.

It may be seen from the foregoing that the second light-emitting unit 31b is formed after the first light-emitting unit 31a, therefore the second encapsulation portion 41b corresponding to the second light-emitting unit 31b is also formed after the first light-emitting unit 31a.

On this basis, in the embodiments of the present application, by controlling that the thickness of the second encapsulation portion 41b is less than the thickness of the first encapsulation portion 41a, and the etching selectivity ratio of the second encapsulation portion 41b to the first encapsulation portion 41a is not less than 1, the etching duration corresponding to the second encapsulation portion 41b is reduced, so that the etching duration corresponding to the second encapsulation portion 41b is less than the etching duration corresponding to the first encapsulation portion 41a, thereby reducing the probability of damaging the first encapsulation portion 41a due to over-etching of the second encapsulation portion 41b, and improving the encapsulation reliability of the first light-emitting unit 31a.

Similarly, in some embodiments, an etching selectivity ratio of the third encapsulation portion 41c to the second encapsulation portion is SR2, and SR2≥1. That is, it means that the etching rate of the third encapsulation portion 41c is not less than the etching rate of the second encapsulation portion 41b.

In such design, the etching duration corresponding to the third encapsulation portion 41c can be reduced, so that the etching duration corresponding to the third encapsulation portion 41c is less than the etching duration corresponding to the second encapsulation portion 41b, and the probability of damaging the second encapsulation portion 41b due to over-etching of the third encapsulation portion 41c may be reduced, thereby improving the encapsulation reliability of the second light-emitting unit 31b.

In some embodiments, a material of the first encapsulation portion 41a is the same as a material of the second encapsulation portion 41b.

In such design, it is not necessary to use different materials to manufacture the first encapsulation portion 41a and the second encapsulation portion 41b, respectively, so that material cost corresponding to the first encapsulation portion 41a and the second encapsulation portion 41b is reduced, and manufacturing cost of the display panel is reduced.

In some embodiments, SR1>1, the first encapsulation portion 41a includes silicon oxide, and the second encapsulation portion 41b includes silicon oxynitride. Under the same condition, an etching rate of silicon oxynitride is often greater than an etching rate of silicon oxide, and the thickness of the second encapsulation portion 41b is less than the thickness of the first encapsulation portion 41a, so that the etching duration corresponding to the second encapsulation portion 41b may be ensured to be less than the etching duration corresponding to the first encapsulation portion 41a, thereby improving manufacturing reliability of the display panel.

In some embodiments, SR2>1, the second encapsulation portion 41b includes silicon oxynitride, and the third encapsulation portion 41c includes silicon nitride. Under the same condition, an etching rate of silicon nitride is often greater than an etching rate of silicon oxynitride, and the thickness of the third encapsulation portion 41c is less than the thickness of the second encapsulation portion 41b, so that the etching duration corresponding to the third encapsulation portion 41c may be ensured to be less than the etching duration corresponding to the second encapsulation portion 41b, thereby improving manufacturing reliability of the display panel.

In a seventh aspect, as shown in FIG. 4, the embodiments of the present application provide a display panel including a substrate 10, an isolation structure 20, a light-emitting functional layer 30, and a first encapsulation layer 40, the isolation structure 20 is provided on a side of the substrate 10, and the isolation structure 20 encloses and forms a plurality of opening structures 21. The light-emitting functional layer 30 is provided on a side of the substrate 10 and includes a plurality of light-emitting units 31 provided within a plurality of opening structures 31. The first encapsulation layer 40 is provided on a side of the light-emitting functional layer 30 away from the substrate 10 and includes a plurality of encapsulation portions 41 corresponding to the plurality of light-emitting units 31.

The encapsulation portion 41 includes a first sub-portion 413 in contact with the first isolation portion 22, a second sub-portion 414 connected to a side of the first sub-portion 413 away from the substrate 10, and a third sub-portion 415 connected to a side of the first sub-portion 413 facing the substrate 10.

In the manufacturing process of the encapsulation portion 41, a corresponding encapsulation material may extend along a sidewall of the isolation structure 20, so that the formed encapsulation portion 41 can include the first sub-portion 413, the second sub-portion 414, and the third sub-portion 415, here, the first sub-portion 413 is in contact with a sidewall of the first isolation portion 22, and the second sub-portion 414 may partially be in contact with a sidewall of the second isolation portion 23 and partially extend to a side of the second isolation portion 23 away from the substrate 10, and the third sub-portion 415 covers the light-emitting unit 31.

It may be seen from the foregoing that, in the embodiments of the present application, thicknesses of different encapsulation portions 41 may be different, so that different encapsulation portions 41 may correspond to different microscopic appearances. Optionally, in at least a part of the encapsulation portions 41, the second sub-portion 414 is connected to the third sub-portion 415, that is, the first sub-portion 413, the second sub-portion 414, and the third sub-portion 415 can together form an enclosed space. And/or in at least a part of the encapsulation portions 41, the second sub-portion 414 is spaced apart from the third sub-portion 415, that is, the first sub-portion 413, the second sub-portion 414 and the third sub-portion 415 can together form a space having an opening.

In some optional embodiments, the plurality of encapsulation portions 41 includes a first encapsulation portion 41a and a second encapsulation portion 41b. Thicknesses of the first encapsulation portion 41a and the second encapsulation portion 41b are different. In the first encapsulation portion 41a, the second sub-portion 414 is connected to the third sub-portion 415, and in the second encapsulation portion 41b, the second sub-portion 414 is spaced apart from the third sub-portion 415.

In conjunction with the foregoing, it may be seen that since thicknesses of the encapsulation portions 41 are different, microscopic appearances corresponding to different encapsulation portions 41 are different. Further, in the first encapsulation portion 41a, the second sub-portion 414 is connected to the third sub-portion 415, that is, the first sub-portion 413, the second sub-portion 414, and the third sub-portion 415 in the first encapsulation portion 41a can together form an enclosed space. In the second encapsulation portion 41b, the second sub-portion 414 is spaced apart from the third sub-portion 415, that is, the first sub-portion 413, the second sub-portion 414 and the third sub-portion 415 in the second encapsulation portion 41b can together form a space having an opening. Optionally, the thickness of the first encapsulation portion 41a is greater than the thickness of the second encapsulation portion 41b.

In an eighth aspect, the embodiments of the present application provide a display panel including a substrate 10, an isolation structure 20, a light-emitting functional layer 30, and a first encapsulation layer 40, the isolation structure 20 is provided on a side of the substrate 10, and the isolation structure 20 encloses and forms a plurality of opening structures 21. The light-emitting functional layer 30 is provided on a side of the substrate 10 and includes a plurality of light-emitting units 31 provided within a plurality of opening structures 31. The first encapsulation layer 40 is provided on a side of the light-emitting functional layer 30 away from the substrate 10 and includes a plurality of encapsulation portions 41 corresponding to the plurality of light-emitting units 31. Here, thicknesses of encapsulation portions 41 corresponding to at least two adjacent light-emitting units 31 are different.

In the embodiments of the present application, at least two light-emitting units 31 are formed in different processes, respectively, and on this basis, the thicknesses of the encapsulation portions 41 corresponding to at least two adjacent light-emitting units 31 are set to be different, and a thickness of an encapsulation portion 41 corresponding to a light-emitting unit 31 formed previously is relatively great, so that the damage to the encapsulation portion 41 corresponding to the light-emitting unit 31 formed previously due to an etching treatment on the subsequent light-emitting unit 31 and the corresponding encapsulation material is reduced, the risk of the failure of a part of the light-emitting units 31 is reduced, and the usage reliability of the display panel is improved.

In a ninth aspect, the embodiments of the present application provide a display panel including a substrate 10, a light-emitting functional layer 30, and a first encapsulation layer 40. The light-emitting functional layer 30 is provided on a side of the substrate 10 and includes a plurality of light-emitting units 31. The first encapsulation layer 40 is provided on a side of the light-emitting functional layer 30 away from the substrate 10 and includes a plurality of encapsulation portions 41 corresponding to the plurality of light-emitting units 31. Here, etching durations corresponding to the encapsulation portions 41 corresponding to at least a part of the light-emitting units 31 having different light-emitting colors are different.

In the embodiments of the present application, according to the manufacturing sequence of the light-emitting units 31 in the display panel, etching durations of the encapsulation portions 41 corresponding to at least a part of the light-emitting units 31 having different light-emitting colors are set to be different, thereby reducing the risk of failure of a part of the light-emitting units 31 caused by the damage to the encapsulation portions 41 corresponding to the light-emitting units 31 formed previously due to the etching treatment of the subsequent light-emitting unit 31 and the corresponding encapsulation material, and improving the usage reliability of the display panel.

In some embodiments, the encapsulation portion 41 includes a first portion 411, the first portion 411 is a portion of the encapsulation portion 41 located above the light-emitting unit 31, and etching durations corresponding to first portions 411 corresponding to at least a part of the light-emitting units 31 having different light-emitting colors are different.

In the embodiments of the present application, thicknesses of first portions 411 of different encapsulation portions 41 may be adjusted to be different, so that etching durations corresponding to different first portions 411 are different. Optionally, the plurality of light-emitting units 31 include a first light-emitting unit 31a, a second light-emitting unit 31b, and a third light-emitting unit 31c having light-emitting colors different from each other.

The plurality of encapsulation portions 41 include a first encapsulation portion 41a located on a side of the first light-emitting unit 31a away from the substrate 10, a second encapsulation portion 41b located on a side of the second light-emitting unit 31b away from the substrate 10, and a third encapsulation portion 41c located on a side of the third light-emitting unit 31c away from the substrate 10. An etching duration of the first encapsulation portion 41a is greater than an etching duration of at least one of the second encapsulation portion 41b and the third encapsulation portion 41c.

In some optional embodiments, the etching duration of the second encapsulation portion 41b is greater than an etching duration of the third encapsulation portion 41c, or the etching duration of the second encapsulation portion 41b is equal to the etching duration of the third encapsulation portion 41c.

In some embodiments, the plurality of light-emitting units 31 include a first light-emitting unit 31a and a second light-emitting unit 31b having light-emitting colors different from each other, the plurality of encapsulation portions 41 include a first encapsulation portion 41a located on a side of the first light-emitting unit 31a away from the substrate 10 and a second encapsulation portion 41b located on a side of the second light-emitting unit 31b away from the substrate 10, and an etching duration of the first encapsulation portion 41a is greater than an etching duration of the second encapsulation portion 41b. The first light-emitting unit 31a is configured to emit blue light, and the second light-emitting unit 31b is configured to emit red light or green light.

Optionally, the plurality of light-emitting units 31 further include a third light-emitting unit 31c having a light-emitting color different from light-emitting colors of the first light-emitting unit 31a and the second light-emitting unit 31b, the plurality of encapsulation portions 41 include a third encapsulation portion 41c located on a side of the third light-emitting unit 31c away from the substrate 10, the etching duration of the second encapsulation portion 41b is greater than an etching duration of the third encapsulation portion 41c, or the etching duration of the second encapsulation portion 41b is equal to the etching duration of the third encapsulation portion 41c, the first light-emitting unit 31a is configured to emit blue light, the second light-emitting unit 31b is configured to emit green light, and the third light-emitting unit 31c is configured to emit red light.

In some embodiments, etching durations of the encapsulation portions 41 corresponding to the light-emitting units 31 having the same light-emitting color are the same.

In some embodiments, etching durations of the encapsulation portions 41 corresponding to at least two adjacent light-emitting units 31 are different.

In a tenth aspect, referring to FIG. 8, the embodiments of the present application provide a flexible display apparatus including the display panel according to any of the above embodiments.

The flexible display apparatus according to the embodiments of the present application has the beneficial effect of the display panel according to any of the above embodiments, and the reference should be made to the above description of the beneficial effects of the display panel for the details, which is not repeated in the embodiments of the present application.

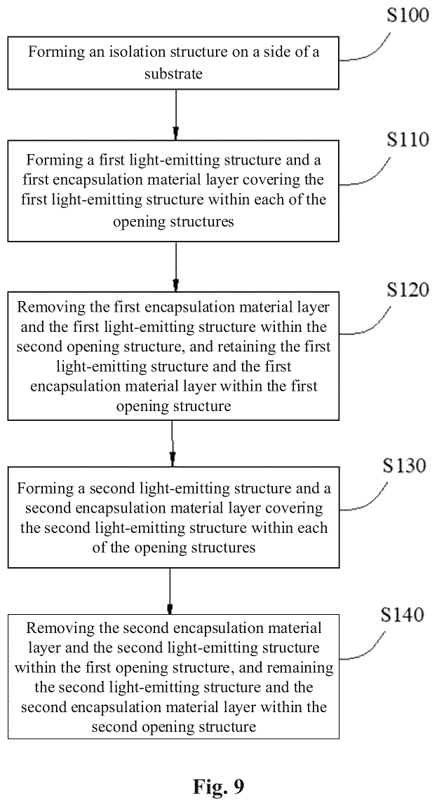

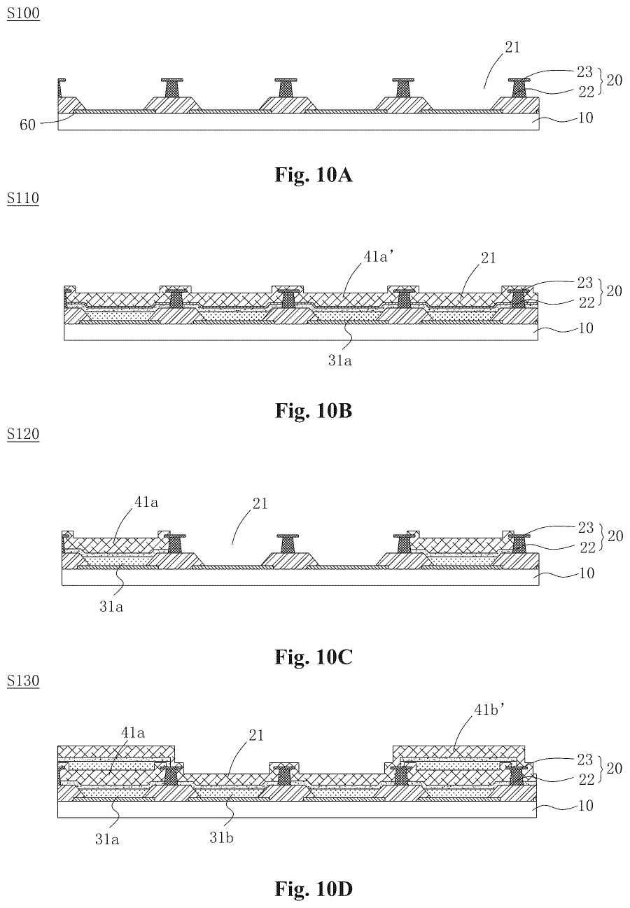

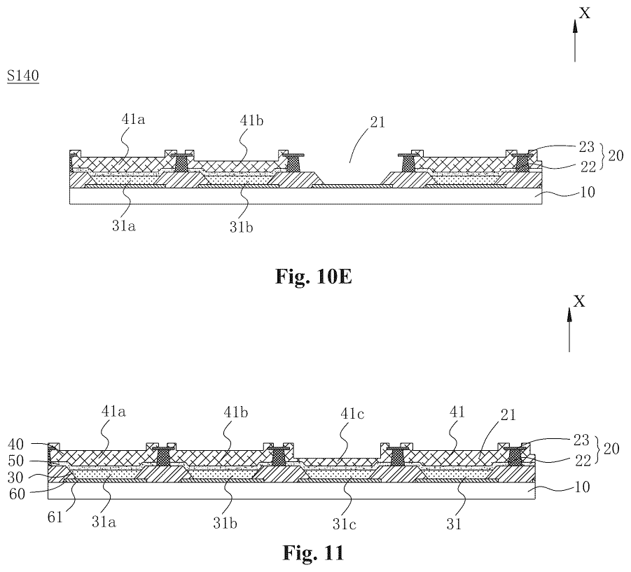

In an eleventh aspect, referring to FIG. 9 and FIG. 10A-10E, the embodiments of the present application provide a method for manufacturing a display panel, including:

S100: forming an isolation structure at one side of a base plate.

Referring to FIG. 10A, in step S100, the isolation structure 20 encloses and forms a plurality of opening structures 21, and the specific structure of the isolation structure 20 is not limited in the embodiments of the present application. In an example, the isolation structure 20 includes a first isolation portion 22 and a second isolation portion 23 provided in sequence along a direction away from the substrate 10, an orthographic projection of the first isolation portion 22 on the substrate 10 is located within an orthographic projection of the second isolation portion 23 on the substrate 10, and the plurality of opening structures 21 include at least one first opening structure and at least one second opening structure, the first opening structure is configured to accommodate a first light-emitting unit 31a subsequently, and the second opening structure is configured to accommodate a second light-emitting unit 31b subsequently.

S110: forming a first light-emitting unit and a first encapsulation material layer covering the first light-emitting unit within each of the opening structures.

Referring to FIG. 10B, in step S110, due to the presence of the isolation structure 20, the first light-emitting unit 31a is formed in a corresponding opening structure 21, and first light-emitting units 31a located within different opening structures 21 are spaced apart from each other. However, a first encapsulation material layer 41a′ may be an integral structure.

S120: by performing an etching treatment on the first encapsulation material layer and the first light-emitting unit within the second opening structure, removing the first encapsulation material layer and the first light-emitting unit within the second opening structure, and retaining the first light-emitting unit and the first encapsulation material layer within the first opening structure.

Referring to FIG. 10C, in step S120, by performing an etching treatment or the like on the first encapsulation material layer, first encapsulation portions 41a corresponding to a part of the first light-emitting units 31a may be formed. Then, the first light-emitting unit 31a within the second opening structure is removed, that is, a part of first light-emitting units 31a which are not correspondingly provided with the first encapsulation portions 41a are removed by a process such as etching. Here, an etching duration corresponding to the first encapsulation material layer is T1.

S130: forming a second light-emitting unit and a second encapsulation material layer covering the second light-emitting unit within each of the opening structures.

Referring to FIG. 10D, in step S130, due to the presence of the isolation structure 20, the second light-emitting unit 31b is formed in the corresponding opening structure 21, here, a part of second light-emitting units 31b cover first encapsulation portions 41a on the first light-emitting units 31a, and the second light-emitting units 31b located within the different opening structures 21 are spaced apart from each other. The second encapsulation material layer may be an integral structure. Here, a thickness of the first encapsulation material layer is greater than a thickness of a second encapsulation material layer 41b′. The thickness of the first encapsulation layer 41a′ refers to a thickness of the first encapsulation layer 41b′ on the first light-emitting unit 31a, and the thickness of the second encapsulation layer 41b′ refers to a thickness of the second encapsulation layer 41b′ on the second light-emitting unit 31b.

S140: by performing an etching treatment on the second light-emitting unit and the second encapsulation material layer within the first opening structure, removing the second encapsulation material layer and the second light-emitting unit within the first opening structure, and retaining the second light-emitting unit and the second encapsulation material layer within the second opening structure.

Referring to FIG. 10E, in step S140, processing the second encapsulation material layer and the second light-emitting unit 31b is similar to processing the first encapsulation material layer and the first light-emitting unit 31a, which is not repeated in the embodiments of the present application. An etching duration corresponding to the second encapsulation material layer is T2, and T1>T2.

In this process, since the etching duration of the second encapsulation material layer is less than the etching duration of the first encapsulation material layer, the probability of excessively damaging the first encapsulation portion 41a due to the etching treatment on the second encapsulation material layer and the second light-emitting unit 31b may be reduced, thereby ensuring that the first encapsulation portion 41a can encapsulate and protect the first light-emitting unit 31a, and improving the reliability of the display panel.

It should be noted that how to control the etching durations of the first encapsulation material layer and the second encapsulation material layer is not limited in the embodiments of the present application. In an example, the thickness of the first encapsulation layer may be controlled to be greater than the thickness of the second encapsulation layer, so that T1>T2; or a material of the first encapsulation material layer may be controlled to be different from a material of the second encapsulation material layer, so that an etching selectivity ratio of the second encapsulation material layer to the first encapsulation material layer is SR1≥1, and thus T1>T2.

Moreover, under a condition that the thickness of the first encapsulation material layer 41a′ is greater than the thickness of the second encapsulation material layer 41b′, and since a part of the material in the first encapsulation material layer 41a′ may be removed in the etching process performed on the second encapsulation material layer 41b′, a thickness of a finally formed first encapsulation portion 41a may be greater than the thickness of the second encapsulation portion 41b.

It should be noted that, as shown in FIG. 11, after step S140 is completed, a third light-emitting unit 31c and a corresponding third encapsulation portion 41c may be formed, which is not limited in the embodiments of the present application.

In some embodiments, the thickness of the first encapsulation material layer is greater than the thickness of the second encapsulation material layer; and/or, an etching selectivity ratio of the second encapsulation material layer to the first encapsulation material layer is SR1, and SR1≥1.

In the related art, the manufacturing sequence of the light-emitting units 31 in the display panel may be determined according to light-emitting stability corresponding to different light-emitting units 31. Specifically, a corresponding light-emitting unit 31 having high light-emitting stability is often formed first, that is, a light-emitting unit 31 less susceptible to failure and denaturation is formed first, and then a light-emitting unit 31 having poor light-emitting stability is formed. Further, manufacturing sequence of the first light-emitting units 31a is often before manufacturing sequence of the second light-emitting units 31b.

The “light-emitting stability” mentioned in the embodiments of the present application refers to a duration in which a corresponding light-emitting material fails and denatures under a certain condition. The higher the light-emitting stability is, the less susceptible the corresponding light-emitting unit 31 is to the failure and the denaturation, and service life thereof is often longer.

In view of this, in the embodiments of the present application, according to the manufacturing sequence corresponding to the light-emitting unit 31, a thickness of an encapsulation portion 41 corresponding to a first light-emitting unit 31a having the high light-emitting stability is greater than a thickness of the encapsulation portion 41 corresponding to the second light-emitting unit 31b, thereby reducing the probability of the encapsulation portion 41 corresponding to the first light-emitting unit 31a being damaged under a condition that the etching treatment is performed on the second light-emitting unit 31b, the encapsulation portion 41 of the second light-emitting unit 31b and the like, which is helpful for improving the encapsulation reliability of the first light-emitting structure. Optionally, the first light-emitting unit 31a is configured to emit red light or green light, and the second light-emitting unit 31b is configured to emit blue light.

In some embodiments, after step S140, the method further includes:

S150: forming a third light-emitting unit and a third encapsulation material layer covering the third light-emitting unit within each of the opening structures.

S160: by performing an etching treatment on the third encapsulation material layer and the third light-emitting unit within the first opening structure and the second opening structure, removing the third encapsulation material layer and the third light-emitting unit within the first opening structure and the second opening structure. Here, an etching duration of the second encapsulation material layer is greater than an etching duration of the third encapsulation material layer, or the etching duration of the second encapsulation material layer is equal to the etching duration of the third encapsulation material layer.

In a twelfth aspect, the embodiments of the present application provide a method for manufacturing a display panel, including:

S100: forming an isolation structure at one side of a base plate.

Referring to FIG. 10A, in step S100, the isolation structure 20 encloses and forms an opening structure 21, a plurality of opening structures 21 include at least one first opening structure and at least one second opening structure. The specific structure of the isolation structure 20 is not limited in the embodiments of the present application. In an example, the isolation structure 20 includes a first isolation portion 22 and a second isolation portion 23 provided in sequence along a direction away from the substrate 10, and an orthographic projection of the first isolation portion 22 on the substrate 10 is located within an orthographic projection of the second isolation portion 23 on the substrate 10.

S110: forming a first light-emitting unit and a first encapsulation material layer covering the first light-emitting unit within each of the opening structures.

Referring to FIG. 10B, in step S110, due to the presence of the isolation structure 20, the first light-emitting unit 31a is formed in a corresponding opening structure 21, and first light-emitting units 31a located within different opening structures 21 are spaced apart from each other. However, a first encapsulation material layer 41a′ may be an integral structure.

S120: removing the first encapsulation material layer and the first light-emitting unit within the second opening structure, and remaining the first light-emitting unit and the first encapsulation material layer within the first opening structure.

Referring to FIG. 10C, in step S120, by performing an etching treatment or the like on the first encapsulation material layer, first encapsulation portions 41a corresponding to a part of the first light-emitting units 31a may be formed. Then, the first light-emitting unit 31a within the second opening structure is removed, that is, a part of first light-emitting units 31a which are not correspondingly provided with the first encapsulation portions 41a are removed by a process such as etching. Here, an etching duration corresponding to the first encapsulation material layer is T1.

S130: forming a second light-emitting unit and a second encapsulation material layer covering the second light-emitting unit within each of the opening structures.

Referring to FIG. 10D, in step S130, due to the presence of the isolation structure 20, the second light-emitting unit 31b is formed in a corresponding opening structure 21, and second light-emitting units 31b located within different opening structures 21 are spaced apart from each other. The second encapsulation material layer may be an integral structure. Here, a thickness of the first encapsulation material layer is greater than a thickness of a second encapsulation material layer 41b′.

S140: removing the second encapsulation material layer and the second light-emitting unit within the first opening structure, and remaining the second light-emitting unit and the second encapsulation material layer within the second opening structure.

Referring to FIG. 10E, in step S140, processing the second encapsulation material layer and the second light-emitting unit 31b is similar to processing the first encapsulation material layer and the first light-emitting unit 31a, which is not repeated in the embodiments of the present application. An etching duration corresponding to the second encapsulation material layer is T2, and T1>T2.

In this process, since the thickness of the first encapsulation material layer is greater than the thickness of the second encapsulation material layer, the etching duration of the second encapsulation material layer is less than the etching duration of the first encapsulation material layer, so that the probability of damaging the first encapsulation portion 41a due to the etching treatment on the second encapsulation material layer and the second light-emitting unit 31b may be reduced, thereby ensuring that the first encapsulation portion 41a can encapsulate and protect the first light-emitting unit 31a, and improving the reliability of the display panel.

In some embodiments, after step S140, the method further includes:

S150: forming a third light-emitting unit and a third encapsulation material layer covering the third light-emitting unit within each of the opening structures.

S160: removing the third encapsulation material layer and the third light-emitting unit within the first opening structure and the second opening structure, and remaining the third light-emitting unit and the third encapsulation material layer within the third opening structure.

Here, a thickness of the second encapsulation material layer is greater than a thickness of the third encapsulation material layer, or the thickness of the second encapsulation material layer is equal to the thickness of the third encapsulation material layer.

Although the implementations disclosed in the present application are described above, the foregoing is described only for the understanding of the present application and is not intended to limit the invention. Modifications and variations in forms and details may be made by any person skilled in the art related to the present application without departing from the gist and scope disclosed in the present application, but the protection scope of the present application is defined only by the scope of the appended claims.

The above are only specific implementations of the present application, those skilled in the art may clearly understand that the other alternatives of the above connections may be referred to the corresponding processes in the foregoing method embodiments, which is not repeated here for the convenience and brevity of the description. It should be understood that the protection scope of the present application is not limited to this, and any person skilled in the art can easily think of various equivalent modifications or replacements within the technical scope disclosed in the present application, and these modifications or replacements should all be covered within the scope of protection of the present application.

What is claimed is:

1. A display panel, comprising:
a substrate;
an isolation structure provided on a side of the substrate, wherein the isolation structure encloses and forms a plurality of opening structures;
a light-emitting functional layer provided on a side of the substrate, wherein the light-emitting functional layer comprises a plurality of light-emitting units provided within the plurality of opening structures; and
a first encapsulation layer provided on a side of the light-emitting functional layer away from the substrate, wherein the first encapsulation layer comprises a plurality of encapsulation portions corresponding to the light-emitting units;
wherein thicknesses of the encapsulation portions corresponding to at least a part of the light-emitting units having different light-emitting colors are different.

2. The display panel according to claim 1, wherein
the encapsulation portion comprises a first portion, an orthographic projection of the first portion on the substrate is located outside an orthographic projection of the isolation structure on the substrate, and thicknesses of first portions corresponding to at least a part of the light-emitting units having different colors are different;
the isolation structure comprises a first isolation portion and a second isolation portion provided in sequence along a direction away from the substrate, and an orthographic projection of the first isolation portion on the substrate is located within an orthographic projection of the second isolation portion on the substrate; and
the orthographic projection of the first portion on the substrate is located outside the orthographic projection of the second isolation portion on the substrate.

3. The display panel according to claim 1, wherein each of the encapsulation portions comprises a second portion located on a side of the isolation structure away from the substrate, and for the plurality of encapsulation portions corresponding to the light-emitting units having different light-emitting colors, thicknesses of second portions of the plurality of encapsulation portions are different.

4. The display panel according to claim 1, wherein the plurality of light-emitting units comprise a first light-emitting unit, a second light-emitting unit, and a third light-emitting unit having light-emitting colors different from each other;
the plurality of encapsulation portions comprise a first encapsulation portion located on a side of the first light-emitting unit away from the substrate, a second encapsulation portion located on a side of the second light-emitting unit away from the substrate, and a third encapsulation portion located on a side of the third light-emitting unit away from the substrate;
a thickness of the first encapsulation portion is greater than a thickness of at least one of the second encapsulation portion and the third encapsulation portion.

5. The display panel according to claim 4, wherein the thickness of the first encapsulation portion is greater than a thickness of the second encapsulation portion, and the thickness of the second encapsulation portion is greater than a thickness of the third encapsulation portion; or
the thickness of the first encapsulation portion is greater than the thickness of the second encapsulation portion, and the thickness of the second encapsulation portion is equal to the thickness of the third encapsulation portion; or
the thickness of the first encapsulation portion is equal to the thickness of the second encapsulation portion, and the thickness of the second encapsulation portion is greater than the thickness of the third encapsulation portion.

6. The display panel according to claim 4, wherein the plurality of light-emitting units comprise a first light-emitting unit and a second light-emitting unit having light-emitting colors different from each other;
the plurality of encapsulation portions comprise a first encapsulation portion located on a side of the first light-emitting unit away from the substrate and a second encapsulation portion located on a side of the second light-emitting unit away from the substrate, and a thickness of the first encapsulation portion is greater than a thickness of the second encapsulation portion;
the plurality of light-emitting units further comprise a third light-emitting unit having a light-emitting color different from light-emitting colors of the first light-emitting unit and the second light-emitting unit;
the plurality of encapsulation portions comprise a third encapsulation portion located on a side of the third light-emitting unit away from the substrate, the thickness of the second encapsulation portion is greater than a thickness of the third encapsulation portion, or the thickness of the second encapsulation portion is equal to the thickness of the third encapsulation portion; and
the first light-emitting unit is configured to emit blue light, the second light-emitting unit is configured to emit green light, and the third light-emitting unit is configured to emit red light; or, the first light-emitting unit is configured to emit red light, the second light-emitting unit is configured to emit green light, and the third light-emitting unit is configured to emit blue light.

7. The display panel according to claim 1, wherein a thickness of at least one of the encapsulation portions is greater than or equal to 1.0 um, and less than or equal to 2.5 um.

8. The display panel according to claim 1, wherein the plurality of light-emitting units comprise a first light-emitting unit and a second light-emitting unit having light-emitting colors different from each other, the plurality of encapsulation portions comprise a first encapsulation portion located on a side of the first light-emitting unit away from the substrate and a second encapsulation portion located on a side of the second light-emitting unit away from the substrate, a thickness of the first encapsulation portion is greater than a thickness of the second encapsulation portion, an etching selectivity ratio of the second encapsulation portion to the first encapsulation portion is SR1, and SR1≥1;
the plurality of light-emitting units further comprise a third light-emitting unit having a light-emitting color different from light-emitting colors of the first light-emitting unit and the second light-emitting unit, and the plurality of encapsulation portions comprise a third encapsulation portion located on a side of the third light-emitting unit away from the substrate;
an etching selectivity ratio of the third encapsulation portion to the second encapsulation portion is SR2, and SR2≥1.

9. The display panel according to claim 1, wherein the isolation structure comprises a first isolation portion and a second isolation portion provided in sequence along a direction away from the substrate, and an orthographic projection of the first isolation portion on the substrate is located within an orthographic projection of the second isolation portion on the substrate; and
the plurality of light-emitting units comprise a first light-emitting unit and a second light-emitting unit having light-emitting colors different from each other, the plurality of opening structures comprise at least one first opening structure and at least one second opening structure, the first light-emitting unit is located within the first opening structure, and the second light-emitting unit is located within the second opening structure;
the plurality of encapsulation portions comprise a first encapsulation portion located on a side of the first light-emitting unit away from the substrate and a second encapsulation portion located on a side of the second light-emitting unit away from the substrate, and a thickness of the first encapsulation portion is greater than a thickness of the second encapsulation portion.

10. The display panel according to claim 9, wherein
a contour line of the orthographic projection of the first isolation portion on the substrate comprises at least one first contour line corresponding to the first opening structure and at least one second contour line corresponding to the second opening structure;
a contour line of the orthographic projection of the second isolation portion on the substrate comprises at least one third contour line corresponding to the first opening structure and at least one fourth contour line corresponding to the second opening structure;
a distance between the first contour line and the third contour line corresponding to the first opening structure is L1, a distance between the second contour line and the fourth contour line corresponding to the second opening structure is L2, and L1<L2;
a length of the second isolation portion extending toward the first opening structure relative to the first isolation portion is L5, a length of the second isolation portion extending toward the second opening structure relative to the first isolation portion is L6, and L5<L6.

11. The display panel according to claim 9, wherein
the display panel further comprises a pixel definition layer comprising a plurality of pixel openings and a pixel definition portion between adjacent pixel openings, the plurality of pixel openings comprises a first pixel opening and a second pixel opening, the first light-emitting unit is located within the first pixel opening, the second light-emitting unit is located within the second pixel opening, the first pixel opening is in communication with the first opening structure, and the second pixel opening is in communication with the second opening structure;
a contour line of the orthographic projection of the first isolation portion on the substrate comprises at least one first contour line corresponding to the first opening structure and at least one second contour line corresponding to the second opening structure;
a contour line of an orthographic projection of the pixel defining portion on the substrate comprises at least one fifth contour line corresponding to the first pixel opening and at least one sixth contour line corresponding to the second pixel opening; and
a distance between the first contour line and the fifth contour line corresponding to the first opening structure is L3, a distance between the second contour line and the fourth contour line corresponding to the second pixel opening is L4, and L3<L4.

12. The display panel according to claim 1, wherein the isolation structure comprises a first isolation portion and a second isolation portion provided in sequence along a direction away from the substrate, and an orthographic projection of the first isolation portion on the substrate is located within an orthographic projection of the second isolation portion on the substrate; and
the encapsulation portion comprises a first sub-portion in contact with the first isolation portion, a second sub-portion connected to a side of the first sub-portion away from the substrate, and a third sub-portion connected to a side of the first sub-portion facing the substrate;
wherein the plurality of encapsulation portions comprise a first encapsulation portion and a second encapsulation portion, and a thickness of the first encapsulation portion is greater than a thickness of the second encapsulation portion; and
in the first encapsulation portion, the second sub-portion is connected to the third sub-portion, and in the second encapsulation portion, the second sub-portion is spaced apart from the third sub-portion.

13. The display panel according to claim 1, wherein the display panel further comprises a first electrode layer provided between the light-emitting functional layer and the first encapsulation layer, and the first electrode layer comprises a plurality of first electrodes corresponding to the plurality of light-emitting units;
the isolation structure comprises a first isolation portion and a second isolation portion provided in sequence along a direction away from the substrate, and an orthographic projection of the first isolation portion on the substrate is located within an orthographic projection of the second isolation portion on the substrate; and
the first isolation portion comprises a conductive material, and the first electrode contacts the first isolation portion.

14. The display panel according to claim 1, wherein the plurality of light-emitting units comprise a first light-emitting unit and a second light-emitting unit having light-emitting colors different from each other, a thickness of the first light-emitting unit is less than a thickness of the second light-emitting unit; and
the plurality of encapsulation portions comprise a first encapsulation portion located on a side of the first light-emitting unit away from the substrate and a second encapsulation portion located on a side of the second light-emitting unit away from the substrate, and a thickness of the first encapsulation portion is greater than a thickness of the second encapsulation portion.

15. The display panel according to claim 14, wherein the first light-emitting unit and the second light-emitting unit each comprise a hole transport layer, an electron transport layer, and a light-emitting material between the hole transport layer and the electron transport layer, and a thickness of a light-emitting material in the first light-emitting unit is less than a thickness of a light-emitting material in the second light-emitting unit.

16. The display panel according to claim 1, wherein the display panel further comprises a second encapsulation layer provided on a side of the first encapsulation layer away from the substrate, the second encapsulation layer covers the plurality of encapsulation portions and comprises a first surface on a side away from the substrate, and the first surface is parallel to a plane where the substrate is located.
the plurality of light-emitting units comprise a first light-emitting unit and a second light-emitting unit having light-emitting colors different from each other, the plurality of encapsulation portions comprise a first encapsulation portion located on a side of the first light-emitting unit away from the substrate and a second encapsulation portion located on a side of the second light-emitting unit away from the substrate, and a thickness of the first encapsulation portion is greater than a thickness of the second encapsulation portion;
a thickness of the second encapsulation layer above the first encapsulation portion is less than a thickness of the second encapsulation layer above the second encapsulation portion.

17. The display panel according to claim 1, wherein the display panel further comprises a third encapsulation layer provided on a side of the second encapsulation layer away from the substrate, and the third encapsulation layer covers the plurality of encapsulation portions; and
the first encapsulation layer and the third encapsulation layer comprise an inorganic material.

18. The display panel according to claim 1, wherein thicknesses of the encapsulation portions corresponding to the light-emitting units having different light-emitting colors are different; and
thicknesses of the encapsulation portions corresponding to the light-emitting units having the same light-emitting color are the same.

19. The display panel according to claim 1, wherein thicknesses of the encapsulation portions corresponding to at least two adjacent light-emitting units are different.

20. A display panel, comprising:
a substrate;
an isolation structure provided on a side of the substrate, wherein the isolation structure encloses and forms a plurality of opening structures;
a light-emitting functional layer provided on a side of the substrate, wherein the light-emitting functional layer comprises a plurality of light-emitting units provided within the plurality of opening structures; and
a first encapsulation layer provided on a side of the light-emitting functional layer away from the substrate, wherein the first encapsulation layer comprises a plurality of encapsulation portions corresponding to the light-emitting units;
wherein etching durations corresponding to the encapsulation portions corresponding to at least a part of the light-emitting units having different light-emitting colors are different.

21. The display panel according to claim 20, wherein
the encapsulation portion comprises a first portion, the first portion is a portion of the encapsulation portion located above the light-emitting unit, and etching durations corresponding to first portions corresponding to at least a part of the light-emitting units having different light-emitting colors are different.

22. The display panel according to claim 20, wherein the plurality of light-emitting units comprise a first light-emitting unit, a second light-emitting unit, and a third light-emitting unit having light-emitting colors different from each other;
the plurality of encapsulation portions comprise a first encapsulation portion located on a side of the first light-emitting unit away from the substrate, a second encapsulation portion located on a side of the second light-emitting unit away from the substrate, and a third encapsulation portion located on a side of the third light-emitting unit away from the substrate;
an etching duration of the first encapsulation portion is greater than an etching duration of at least one of the second encapsulation portion and the third encapsulation portion.

23. The display panel according to claim 22, wherein the etching duration of the first encapsulation portion is greater than an etching duration of the second encapsulation portion, and the etching duration of the second encapsulation portion is greater than an etching duration of the third encapsulation portion; or
the etching duration of the first encapsulation portion is greater than the etching duration of the second encapsulation portion, and the etching duration of the second encapsulation portion is equal to the etching duration of the third encapsulation portion; or
the etching duration of the first encapsulation portion is equal to the etching duration of the second encapsulation portion, and the etching duration of the second encapsulation portion is greater than the etching duration of the third encapsulation portion.

24. The display panel according to claim 20, wherein the plurality of light-emitting units comprise a first light-emitting unit and a second light-emitting unit having light-emitting colors different from each other, the plurality of encapsulation portions comprise a first encapsulation portion located on a side of the first light-emitting unit away from the substrate and a second encapsulation portion located on a side of the second light-emitting unit away from the substrate, and an etching duration of the first encapsulation portion is greater than an etching duration of the second encapsulation portion;
the first light-emitting unit is configured to emit blue light, and the second light-emitting unit is configured to emit red light or green light.

25. The display panel according to claim 24, wherein the plurality of light-emitting units further comprise a third light-emitting unit having a light-emitting color different from light-emitting colors of the first light-emitting unit and the second light-emitting unit;
the plurality of encapsulation portions comprise a third encapsulation portion located on a side of the third light-emitting unit away from the substrate, the etching duration of the second encapsulation portion is greater than an etching duration of the third encapsulation portion, or the etching duration of the second encapsulation portion is equal to the etching duration of the third encapsulation portion; and
the first light-emitting unit is configured to emit blue light, the second light-emitting unit is configured to emit green light, and the third light-emitting unit is configured to emit red light.

26. The display panel according to claim 20, wherein etching durations of the encapsulation portions corresponding to the light-emitting units having the same light-emitting color are the same.

27. The display panel according to claim 20, wherein etching durations of the encapsulation portions corresponding to at least two adjacent light-emitting units are different.

28. A method for manufacturing a display panel, comprising:
forming an isolation structure on a side of a substrate, wherein the isolation structure encloses and forms a plurality of opening structures, and the plurality of opening structures comprise at least one first opening structure and at least one second opening structure;
forming a first light-emitting unit and a first encapsulation material layer covering the first light-emitting unit within each of the opening structures;
performing an etching treatment on the first light-emitting unit and the first encapsulation material layer within the second opening structure, and remaining the first light-emitting unit and the first encapsulation material layer within the first opening structure, wherein an etching duration corresponding to the first encapsulation material layer is T1;
forming a second light-emitting unit and a second encapsulation material layer covering the second light-emitting unit within the second opening structure and on the first encapsulation material layer;
performing an etching treatment on the second light-emitting unit and the second encapsulation material layer on the first encapsulation material layer, and remaining the second light-emitting unit and the second encapsulation material layer within the second opening structure, wherein an etching duration corresponding to the second encapsulation material layer is T2, and T1>T2.

29. The method according to claim 28, wherein a thickness of the first encapsulation material layer is greater than a thickness of the second encapsulation material layer; or
an etching selectivity ratio of the second encapsulation material layer to the first encapsulation material layer is SR1, and SR1≥1.

30. The method according to claim 28, wherein the plurality of opening structures further comprise at least one third opening structure; and
after performing the etching treatment on the second light-emitting unit and the second encapsulation material layer on the first encapsulation material layer, and remaining the second light-emitting unit and the second encapsulation material layer within the second opening structure, the method further comprises:
forming a third light-emitting unit and a third encapsulation material layer covering the third light-emitting unit within the third opening structure and on the first encapsulation material layer and the second encapsulation material layer; and
performing an etching treatment on the third light-emitting unit and the third encapsulation material layer on the first encapsulation material layer and the second encapsulation material layer, and remaining the third light-emitting unit and the third encapsulation material layer within the third opening structure;
wherein an etching duration of the second encapsulation material layer is greater than an etching duration of the third encapsulation material layer, or the etching duration of the second encapsulation material layer is equal to the etching duration of the third encapsulation material layer.
